(19) United States
(12) Patent Application Publication
(10) Pub. No.: US 2009/0040726 A1
(43) Pub. Date: Feb. 12, 2009

(54) Vapor chamber structure and method for manufacturing the same

(76) Inventors: Paul Hoffman, San Diego, CA (US); Rajiv Tandon, San Diego, CA (US); Ralph Remsburg, San Diego, CA (US); Tadej Semenic, San Diego, CA (US); Chu-Wan Hong, San Diego, CA (US); Che-Yin Lee, San Diego, CA (US)

Correspondence Address: ROSENBERG, KLEIN & LEE, 3458 ELLICOTT CENTER DRIVE-SUITE 101, ELLICOTT CITY, MD, 21043, US

(21) Appl. No.: 11/889,074

(22) Filed: Aug. 9, 2007

(51) Int. Cl. H05K 7/20; B21D 53/02

(52) U.S. Cl. 361/700; 29/890.032; 361/695; 361/703

(57) ABSTRACT

A vapor chamber structure includes a casing, a working fluid, a wick layer, a plurality of structure strengthening bodies, and a plurality of backflow accelerating bodies. The casing has an airtight vacuum chamber. The working fluid is filled into the airtight vacuum chamber. The wick layer is formed on a surface of the airtight vacuum chamber. The structure strengthening bodies are respectively arranged in the airtight vacuum chamber for supporting the casing. The backflow accelerating bodies are respectively arranged in the airtight vacuum chamber for increasing the backflow velocity of the working fluid. Therefore, the present invention can maintain the completeness of the vapor chamber structure and increase the backflow velocity of the working fluid due to the match of the structure strengthening bodies and backflow accelerating bodies. Because the backflow velocity of the working fluid is increased, the heat-transmitting efficiency is increased.

### BACKGROUND OF THE INVENTION

1. Field of the Invention

The present invention relates to a vapor chamber structure and a method for manufacturing the same, and particularly relates to a vapor chamber structure having a structure strengthening function and a method for manufacturing the same.

2. Description of the Related Art

Cooling or heat removal has been one of the major obstacles of the electronic industry. The heat dissipation increases with the scale of integration, the demand for higher performance, and the increase of multi-functional applications. The development of high performance heat transfer devices becomes one of the major development efforts of the industry.

A heat sink is often used for removing the heat from the device or from the system to the ambient. The performance of a heat sink is characterized by the thermal resistance with a lower value representing a higher performance level. This thermal resistance generally consists of the heat-spreading resistance within the heat sink and the convective resistance between the heat sink surface and the ambient environment. To minimize the heat-spreading resistance, highly conductive materials, e.g. copper and aluminum, are typically used to make the heat sink. However, this conductive heat transfer through solid materials is generally insufficient to meet the higher cooling requirements of newer electronic devices. Thus, more efficient mechanisms have been developed and evaluated, and the vapor chamber has been one of those commonly considered mechanisms.

Vapor chambers make use of the heat pipe principle in which heat is carried by the evaporated working fluid and is spread by the vapor flow. The vapor eventually condenses over the cool surfaces, and, as a result, the heat is distributed from the evaporation surface (the interface with the heat source) to the condensation surfaces (the cooling surfaces). If the area of the cooling surfaces is much higher than the evaporating surface, the spreading of heat can be achieved effectively since the phase change (liquid-vapor-liquid) mechanism occurs near isothermal conditions.

Referring to FIG. 1, the prior art provides a vapor chamber 9 that has an airtight casing 90. Moreover, the casing 90 is made of metal material and has a hollow portion 900. The air in the hollow portion 900 is pumped away, and a working fluid (not shown) is filled into the hollow portion 900. The casing 90 has a wick structure 91 formed on an internal wall thereof. The chamber 9 is evacuated and charged with the working fluid, such as distilled water, which boils at normal operating temperatures. External to the vapor chamber 9 there is a heat-generating source such as 92. As the heat-generating source 92 dissipates heat it causes the working fluid to boil and evaporate. The resultant vapor (as the upward arrows) travels to the cooler section of the chamber 9 which in this case is a top where an optional finned structure 93 is located. At this point the vapor condenses giving off its latent heat energy. The condensed fluid (as the downward arrows) now returns down through the wick structure 91 to the bottom of the chamber 9 nearest the heat-generating source 92 where a new cycle occurs.

However, the thin casing 90 is pressed inward during a vacuum-pumping process, so that the thin casing 90 cannot maintain its surface planarization on a top surface and a bottom surface thereof Hence, the thin casing 90 cannot completely contact with the heat-generating source 92 and the heat-transmitting effect between the heat-generating source 92 and the chamber 9 is reduced.

In the same principle, because the chamber 9 always needs to perform heat-absorbing action and heat-releasing action, the thin casing 90 expands when hot and shrinks when cold (the structure of the hollow casing 90 would be deformed easily). Hence, the casing 90 also cannot maintain its surface planarization on the top surface and the bottom surface thereof and the heat-transmitting effect between the heat-generating source 92 and the chamber 9 is reduced.

In the prior art, in order to prevent the thin casing 90 from being deformed, the size of the chamber 9 cannot be large. Hence, the chamber 9 only can be used to dissipate heat from a heat-generating source of small size.

Furthermore, the chamber 9 only uses the wick structure 91 to return the condensed fluid. Hence, the backflow efficiency (ability to return the working fluid to the evaporator portion of the vapor chamber) of the working fluid is limited.

### SUMMARY OF THE INVENTION

One particular aspect of the present invention is to provide a vapor chamber structure and a method for manufacturing the same. The vapor chamber structure of the present invention has improved structural strength due to the usage of one or more structure strengthening bodies.

In order to achieve the above-mentioned aspects, the present invention provides a vapor chamber structure, comprising: a casing, a working fluid, a wick layer, and one or more structure strengthening bodies. The casing has an airtight vacuum chamber. The working fluid is filled into the airtight vacuum chamber. The wick layer is formed on a surface of the airtight vacuum chamber. The structure strengthening bodies are respectively arranged in the airtight vacuum chamber for supporting the casing.

In order to achieve the above-mentioned aspects, the present invention provides a method for manufacturing a vapor chamber structure, comprising: providing a casing that is composed of at least one upper casings and at least one lower casings; forming a wick layer on an internal surface of the casing; arranging one or more structural strengthening bodies into or between the upper casing(s) and the lower casing(s); assembling the upper casing(s) and the lower casing(s) together to form a receiving chamber; pumping away air from the receiving chamber to form an airtight vacuum chamber; and then filling a working fluid into the airtight vacuum chamber and sealing the casing.

Therefore, the present invention can maintain the structural integrity of the vapor chamber due to the use of the structural strengthening bodies and the sealing effect of the vapor chamber is improved.

It is to be understood that both the foregoing general description and the following detailed description are exemplary, and are intended to provide further explanation of the invention as claimed. Other advantages and features of the invention will be apparent from the following description, drawings and claims.

### BRIEF DESCRIPTION OF THE DRAWINGS

The various objects and advantages of the present invention will be more readily understood from the following detailed description when read in conjunction with the appended drawings, in which:

FIG. 1 is a cross-sectional, schematic view of a vapor chamber structure of the prior art;

FIG. 2 is a perspective, exploded view of a vapor chamber structure according to the first embodiment of the present invention;

FIG. 3 is a perspective, assembled view of a vapor chamber structure according to the first embodiment of the present invention;

FIG. 4 is a cross-sectional view along line 4-4 of a vapor chamber structure shown in FIG. 3;

FIG. 5 is a cross-sectional view along line 5-5 of a vapor chamber structure shown in FIG. 3;

FIG. 6 is a schematic view of a structure strengthening body composed of a solid post and an outer wick layer;

FIG. 7 is a schematic view of structure strengthening body composed of an outer metal solid layer and an inner wick layer;

FIG. 8 is a schematic view of a casing with structural strengthening features included in the formation of the casing;

FIG. 9A is a schematic view of structure strengthening bodies with chamfers on their ends;

FIG. 9B is a detail structure of part B of strengthening bodies in FIG. 9A;

FIG. 10A is a cross-sectional, schematic view of a vapor chamber where the joining of certain of the elements to the casing is simplified or accelerated by use of a secondary material on one or more of the surfaces to be joined;

FIG. 10B is a detail structure of part B of strengthening bodies in FIG. 10A;

FIG. 11 is a cross-sectional, schematic view of a vapor chamber whose structural strengthening features are joined as two opposed parts, each part mounted to the opposing casing;

FIG. 12 is a cross-sectional, schematic view of a vapor chamber structure that has one or more indents or impressions in one or more casings that help to locate one or more structure strengthening bodies;

FIG. 13 is a cross-sectional, schematic view of a vapor chamber structure that has one or more bumps or small protrusions in one or more casings that help to locate one or more structure strengthening bodies;

FIG. 14 is a schematic view of a plurality of structure strengthening elements, each joined to each other;

FIG. 15A is a schematic view of a plurality of structure strengthening elements, each joined to each other;

FIG. 15B is a detail view of the structure strengthening elements showing in FIG. 15A;

FIG. 15C is a top view of the structure strengthening elements showing in FIG. 15A;

FIG. 15D is a schematic view of the structure strengthening elements showing in FIG. 15A;

FIG. 16 is a schematic view of a vapor chamber whose has a filling tube or slot integrally formed with the casing;

FIG. 17A is a perspective, assembled view of a vapor chamber having a structural support member or members that extend around a periphery of the vapor chamber;

FIG. 17B is a side view of a vapor chamber having a structural support member or members that extend around a periphery of the vapor chamber;

FIG. 18 is a cross-section, schematic view of a vapor chamber where the wick material(s) completely fill the vacuum chamber;

FIG. 19 is a cross-section, schematic view of a vapor chamber that utilizes a clad or similar multi-layer material;

FIG. 20 is a cross-section, schematic view of a vapor chamber with seam-sealed edges;

FIG. 21 is a cross-section, schematic view of a vapor chamber with one or more cooling fins or structures formed integrally in one or more of the casings;

FIG. 22A is a top view of a vapor chamber with an outward protrusion, such protrusion being formed integrally with the casing material or by attaching a separate piece (the protrusion) to the casing;

FIG. 22B is a cross-section, schematic view of a vapor chamber with an outward protrusion, such protrusion being formed integrally with the casing material;

FIG. 22C is a cross-section, schematic view of a vapor chamber with an outward protrusion, such protrusion being formed by attaching a separate piece (the protrusion) to the casing;

FIG. 23A is a top plan view of a vapor chamber having a protrusion, such protrusion supported by structural strengthening elements that wrap around and surround certain areas of the vapor chamber, but primarily around the protrusion;

FIG. 23B is a bottom plan view of a vapor chamber having a protrusion, such protrusion supported by structural strengthening elements that wrap around and surround certain areas of the vapor chamber, but primarily around the protrusion;

FIG. 23C is an isometric schematic view of a vapor chamber having a protrusion, such protrusion supported by structural strengthening elements that wrap around and surround certain areas of the vapor chamber, but primarily around the protrusion;

FIG. 23D is a cross-section view of a vapor chamber having a protrusion, such protrusion supported by structural strengthening elements that wrap around and surround certain areas of the vapor chamber, but primarily around the protrusion;

FIG. 24A is a top view of a vapor chamber having a protrusion, such protrusion supported by structure strengthening bodies in the form of posts;

FIG. 24B is a cross-section view of a vapor chamber having a protrusion, such protrusion supported by structure strengthening bodies in the form of posts;

FIG. 25A is a top view of a vapor chamber having a protrusion, such protrusion supported by structure strengthening bodies in the form of ribs or buttresses;

FIG. 25B is a cross-section view of a vapor chamber having a protrusion, such protrusion supported by structure strengthening bodies in the form of ribs or buttresses;

FIG. 26A is a top view of a vapor chamber having a protrusion, such protrusion strengthened by structure strengthening bodies within the material of the protrusion in the form of areas of varying thickness to impart strength to the structure;

FIG. 26B is a cross-section view of a vapor chamber having a protrusion, such protrusion strengthened by structure strengthening bodies within the material of the protrusion in the form of areas of varying thickness to impart strength to the structure;

FIG. 27 is a cross-section, schematic view of a vapor chamber having a plurality of protrusions, such protrusions on one or multiple levels or heights depending on the height of the heat sources to which they are applied;

FIG. 28 is a cross-section, schematic view of a vapor chamber having one or more protrusions, such protrusion(s) forming both a structural element and a heat transfer medium to which are attached one or more fins whose purpose is to dissipate heat to the surrounding environment;

FIG. 29 is an isometric, schematic view of a vapor chamber that includes one or more channels on one or more of its exterior surfaces,

FIG. 30A is a cross-section, schematic and a plan view of an extruded heat sink with radial fins, such heat sink body including a vapor chamber;

FIG. 30B is a top, schematic view of an extruded heat sink with radial fins, such heat sink body including a vapor chamber;

FIG. 31 is a cross-section, schematic view of a vapor chamber formed in the body of an extruded heat sink and also including a mounting bracket and an element that attaches said bracket to the heat sink;

FIG. 32 is a cross-section, schematic view of an extruded heat sink which includes a vapor chamber in the body of the heat sink and to which is attached a fan and fan housing;

FIG. 33A is a cross-section, schematic view of a linear extruded heat sink with linear fins, which includes the formation of a vapor chamber in the body of the heat sink;

FIG. 33B is a top view of a linear extruded heat sink with linear fins, which includes the formation of a vapor chamber in the body of the heat sink;

FIG. 34 is a cross-section, schematic view of a vapor chamber with a double seam seal at its outer periphery of its casings;

FIG. 35 is a flowchart of a method for manufacturing a vapor chamber structure of one embodiment of the present invention;

FIG. 36 is a flowchart of a method for manufacturing a vapor chamber whose edges are seam sealed;

FIG. 37A is a cross-section, schematic drawings showing the sequence of steps in the manufacturing of a vapor chamber whose edges are seam sealed;

FIG. 37B is a cross-section, schematic drawings showing the sequence of steps in the manufacturing of a vapor chamber whose edges are seam sealed;

FIG. 37C is a cross-section, schematic drawings showing the sequence of steps in the manufacturing of a vapor chamber whose edges are seam sealed;

FIG. 37D is a cross-section, schematic drawings showing the sequence of steps in the manufacturing of a vapor chamber whose edges are seam sealed;

FIG. 37E is a cross-section, schematic drawings showing the sequence of steps in the manufacturing of a vapor chamber whose edges are seam sealed; and

FIG. 38 is a flowchart of a method for manufacturing a vapor chamber from an extruded heat sink body with one or more attached fins.

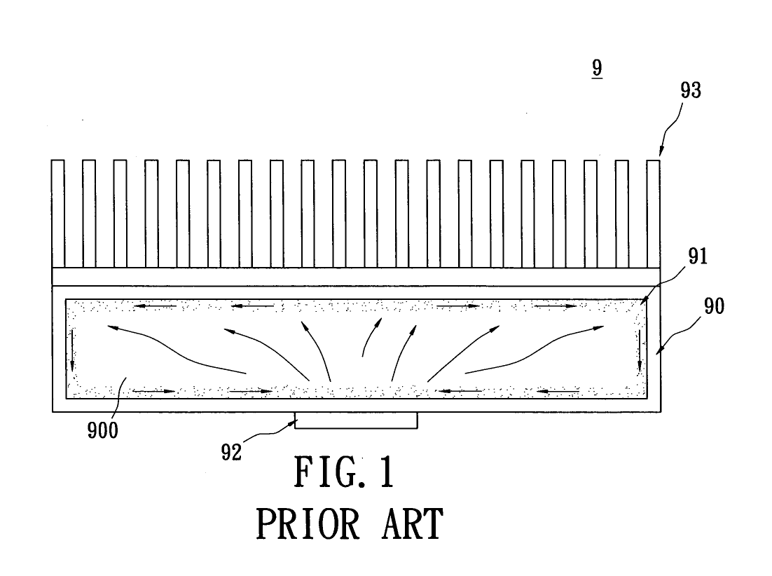

### DETAILED DESCRIPTION OF THE PREFERRED EMBODIMENTS

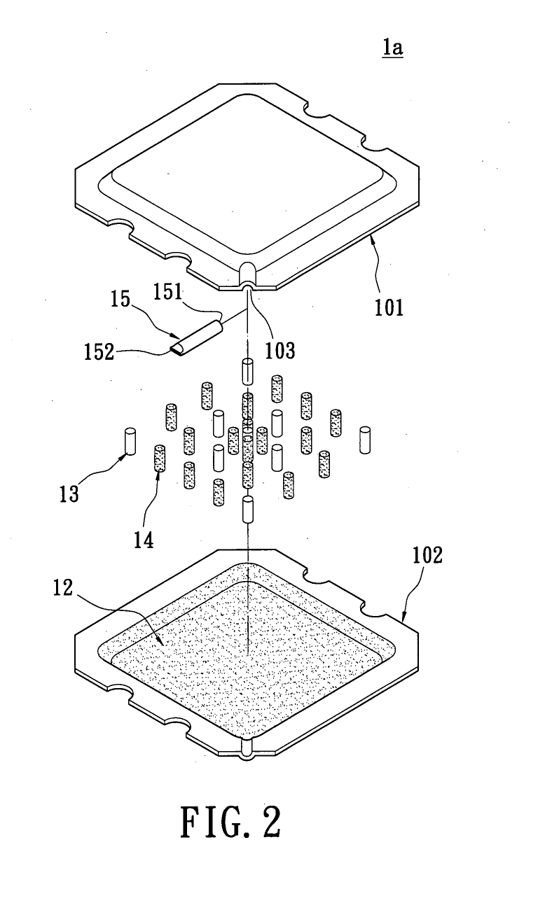

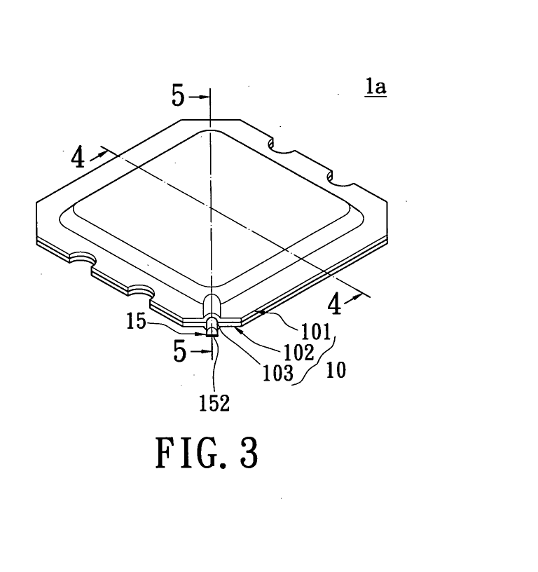

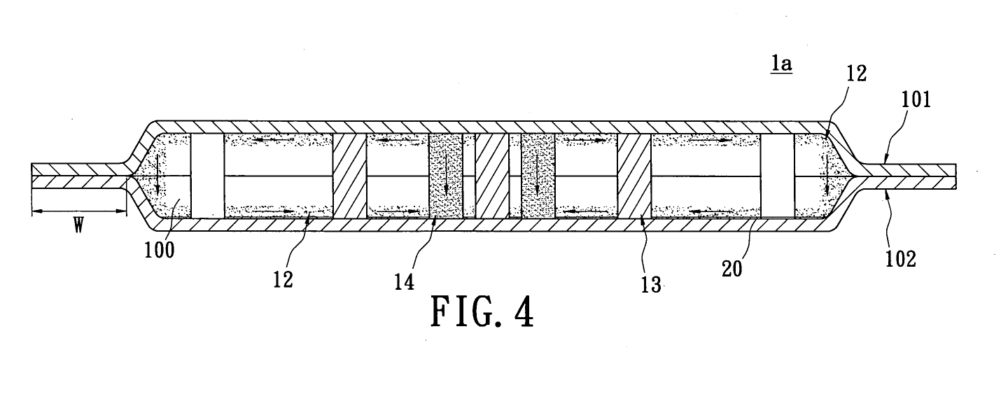

Referring to FIGS. 2 to 5, the first embodiment of the present invention provides a vapor chamber structure 1a, comprising: a casing 10, a working fluid 20, a wick layer 12, and one or more structure strengthening bodies 13.

The casing 10 has an airtight vacuum chamber 100, and the working fluid 20 is filled into the airtight vacuum chamber 100. The casing 10 is composed of one or more upper casings 101 and one or more lower casings 102 that mate with the upper casings 101. Moreover, the casing 10 has contact surfaces between the upper casings 101 and the lower casings 102. The contact surfaces have a predetermined width W, in order to assemble the upper casings 101 and the lower casings 102 easily.

Furthermore, the vapor chamber structure further comprises one or more filling pipes 15 communicated with the airtight vacuum chamber 100 via a joint opening 103 of the casing 10. The filling pipe 15 has an opening side 151 formed on one side thereof and a closed side 152 formed on the other side thereof. The filling pipe 15 is arranged at the periphery of the casing 10 (e.g. a corner). Hence, before the closed side 152 of the filling pipe 15 is sealed, the working fluid 20 can be guided via the filling pipe 15 and be filled into a receiving chamber that is composed of the upper casing 101 and the lower casing 102. Moreover, the air in the receiving chamber is pumped away and the closed side 152 of the filling pipe 15 is sealed, so that the receiving chamber becomes the airtight vacuum chamber 100.

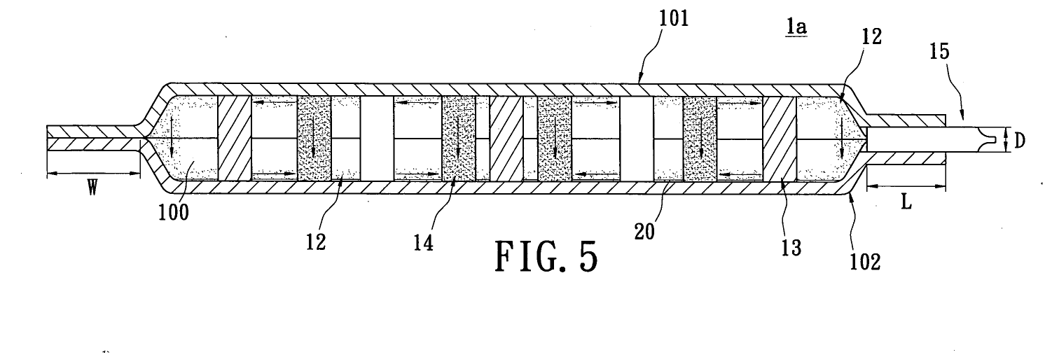

In order to increase the matching between the filling pipe 15 and the joint opening 103 of the casing 10, a contact surface between the casing 10 and the filling pipe 15 has a length L larger than a double length of a diameter D of the filling pipe 15 (L>2D as shown in FIG. 5). Furthermore, in order to increase the surfaces in contact in the joint area the filling pipe 15 can have an ovoid or other non-circular cross-section as shown in FIG. 5. The location of the filling pipe 15 with respect to the periphery of the top casings can be also fixed by features on the filling pipe (e.g. rib or groove) that mate to corresponding features on the casing.

The wick layer 12 is formed on an internal surface of the airtight vacuum chamber 100. The wick layer 12 is made of powders via a sintering method such as ceramic, copper, nickel, brass, bronze or steel powders, or is composed of metal meshes or micro grooves or other materials or geometries that are conducive to enhancing the flow of the working fluid due to capillary forces. Another function of the wick structure is to promote and enhance boiling of the working fluid adjacent to the heat input areas.

The structure strengthening bodies 13 are respectively arranged in the airtight vacuum chamber 100 and between the upper casing 101 and the lower casing 102 for supporting the casing 10. In the first embodiment, each structure strengthening body 13 can be a solid post, and the solid post can be a ceramic, copper, nickel, brass, bronze or steel post or any solid post with high thermal conductivity. Moreover, the structure strengthening bodies 13 are concentrated in a center position (the position of the casing 10 is fragile and is deformed easily) of the airtight vacuum chamber 100. Hence, although the casing 10 is pressed inward during a vacuum-pumping process, the casing 10 can still maintain its surface planarization on a top surface and a bottom surface thereof due to the support of the structure strengthening bodies 13. Therefore, the casing 10 can compactly contact with a heat-generating source (not shown) for increasing heat-transmitting effect between the heat-generating source and the vapor chamber structure 1a.

In the same principle, because the vapor chamber structure la always needs to perform heat-absorbing action and heat-releasing action, the casing 10 expands when hot and shrinks when cold. However, in the present invention, the casing 10 can still maintain its surface planarization on the top surface and the bottom surface thereof due to the support of the structure strengthening bodies 13.

The backflow accelerating bodies 14 are respectively arranged in the airtight vacuum chamber 100 and between the upper casing 101 and the lower casing 102 for increasing the backflow velocity of the working fluid 20. Each backflow accelerating body 14 can be a metal powder post that is formed via a sintering method. Furthermore, the backflow accelerating bodies 14 are dispersed to peripheral positions or other positions that are preferential to the backflow path of the condensed and relatively cold working fluid of the airtight vacuum chamber 100. Furthermore, the structure strengthening bodies 13 are integrally formed with the casing 102 through a powder manufacturing process, such as an injection molding process followed by sintering.

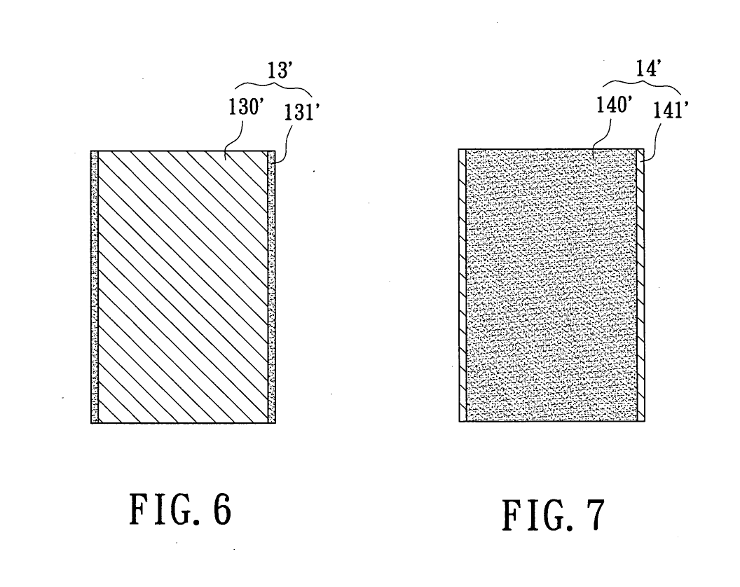

Referring to FIGS. 6 and 7, according to the designer's need, each structure strengthening body 13′ can be composed of a solid post 130′ and a wick layer 131′ circumferentially covering an external surface of the solid post 130′. Each backflow accelerating body 14′ can be composed of a wick post 140′ and a metal solid layer 141′ covered circumferentially on an external surface of the wick post 140′. The wick can be fabricated with any suitable process and materials—to include but not be limited to metal powders, meshes, or small grooves on the surface of the structure strengthening body 13.

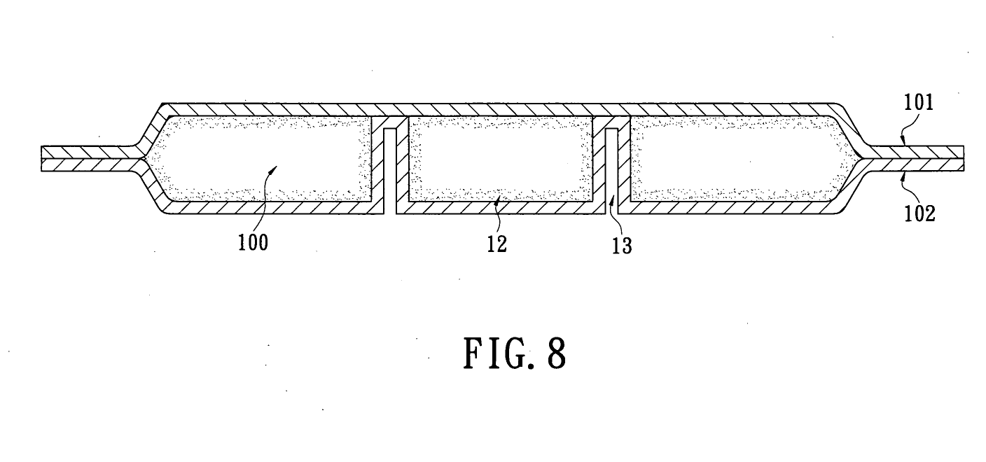

Referring to FIG. 8, a structural strengthening body 13 (e.g. post or rib or other suitable geometry) can be formed directly by shaping one or more of the casings (the bottom casing 102 is shown with shaped structure strengthening bodies in FIG. 8). A wick can be fabricated on the surface of the structural strengthening body 13 with any suitable process and materials—to include but not be limited to metal powders, meshes, or small grooves on the surface of the structure strengthening body 13.

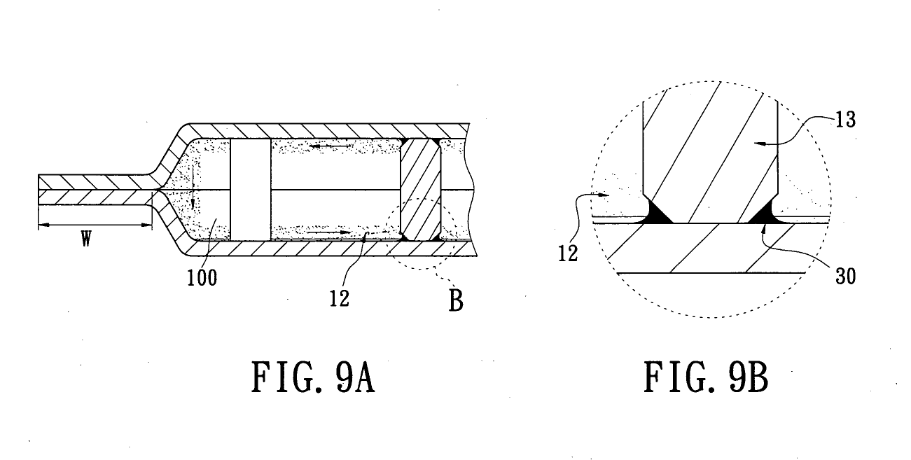

Referring to FIGS. 9A and 9B, a structural strengthening body 13 (e.g. post) can be formed with a chamfered post or other feature that can increase surface tension on and help to retain the joining material 30 (e.g. solder, braze alloy, adhesive or other material) close to the body 13 and importantly so that the joining material 30 does not flow into the pores of the wick 12 which would diminish the performance of the wick.

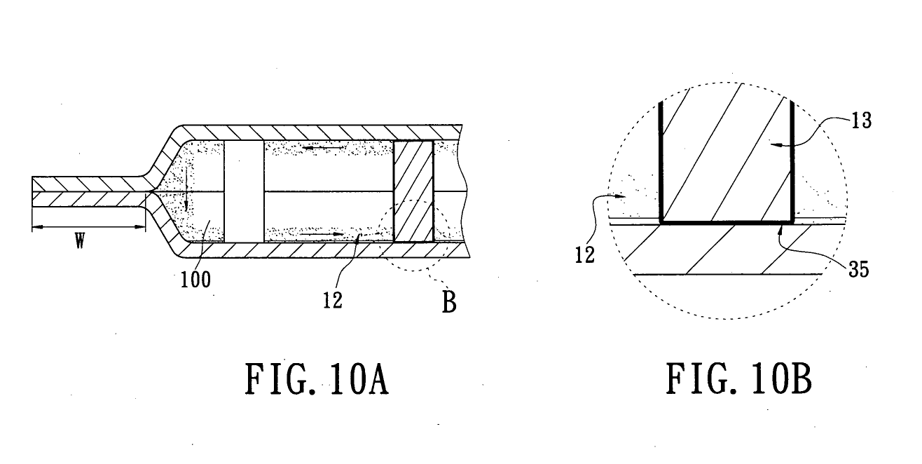

Referring to FIGS. 10A and 10B, a structure strengthening body 13 (e.g. post) can be coated with a suitable material that will promote the adhesion of the element to the casing. For example a copper body 13 could be plated or otherwise coated with a Nickel-Phosphorous material which in conjunction with a Nickel-based braze alloy could accelerate and promote the joining of the body 13 to the casing 102 or 101. It is to be understood that in like manner the coating could be provided on the casing to promote the adhesion of the element to the casing.

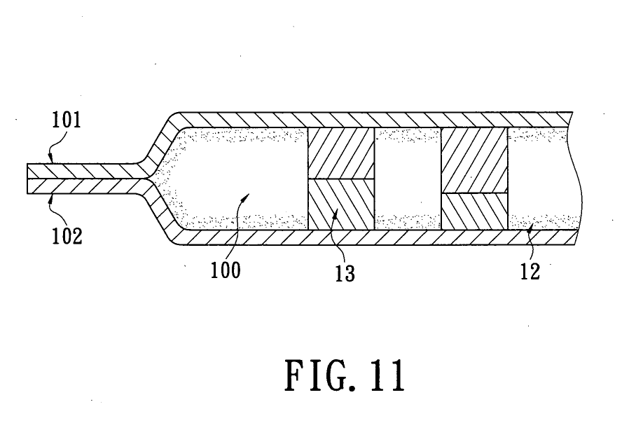

Referring to FIG. 11 structure strengthening bodies 13 are joined as two opposed parts, each part mounted to the opposing casing (101 and 102).

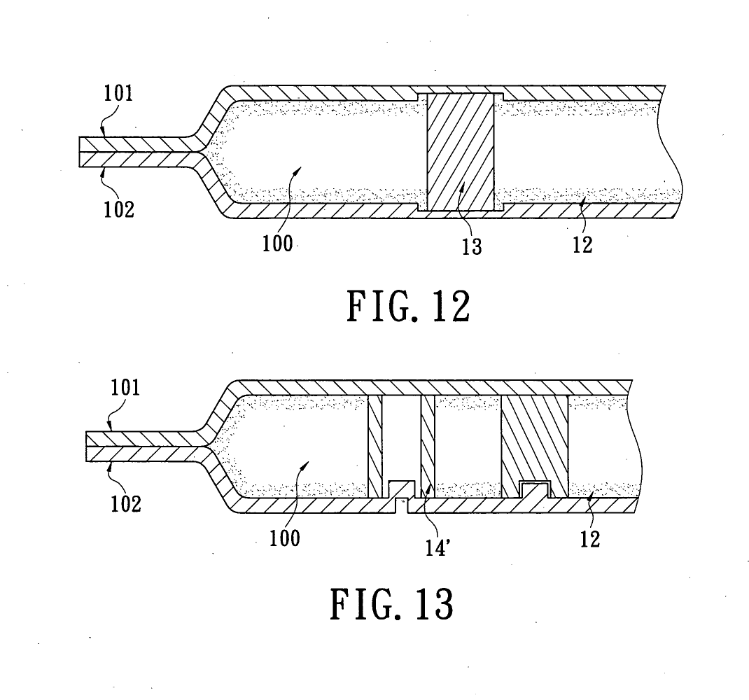

Referring to FIG. 12 the vapor chamber 10 has one or more indents or impressions in one or more casings 101 or 102 that help to locate one or more structure strengthening bodies 13.

Referring to FIG. 13 one or more bumps or small protrusions in one or more casings 101 or 102 help to locate one or more structure strengthening bodies 13 such as a hollow element 14 or a solid element that has a corresponding recess to accept the bump or protrusion. A hollow element 14 can optionally accept a joining material (e.g. braze alloy wire) in its interior space to assist with the joining process and minimize the joining material contact with or intrusion into the wick 12.

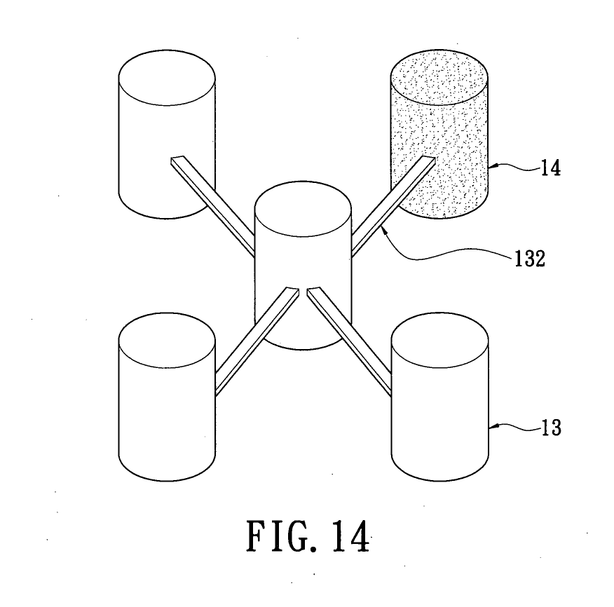

Referring to FIG. 14, a plurality of structure strengthening bodies, either or both solid bodies 13 and porous bodies 14, can be fabricated such that each element is joined to the other elements through a web connecting structure. Such structure could be the result, for example, of runners or webs existent when the structure strengthening bodies 13 are injection molded, pressed and sintered, cast or otherwise manufactured. Having the connecting web structure insures that each structure strengthening body 13 is held securely in geometrical relationship to the other elements, such that when the elements are placed onto a casing of the vapor chamber all the bodies are easily and at once aligned.

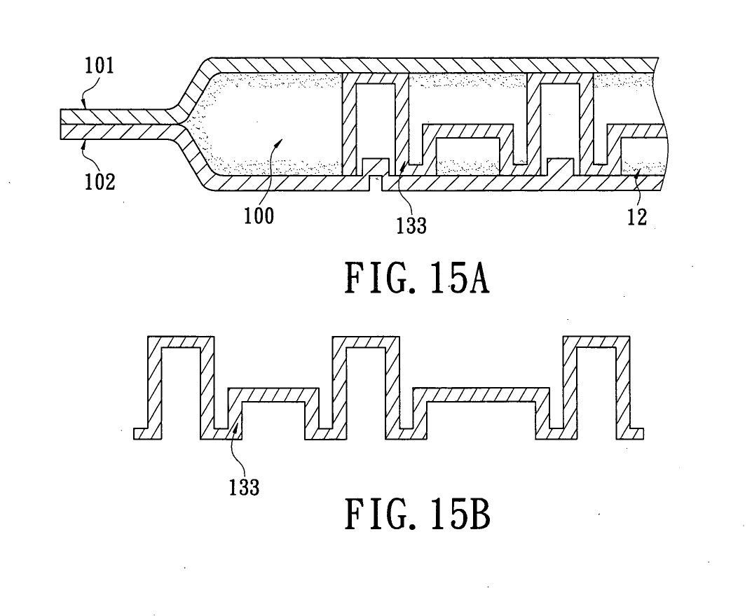

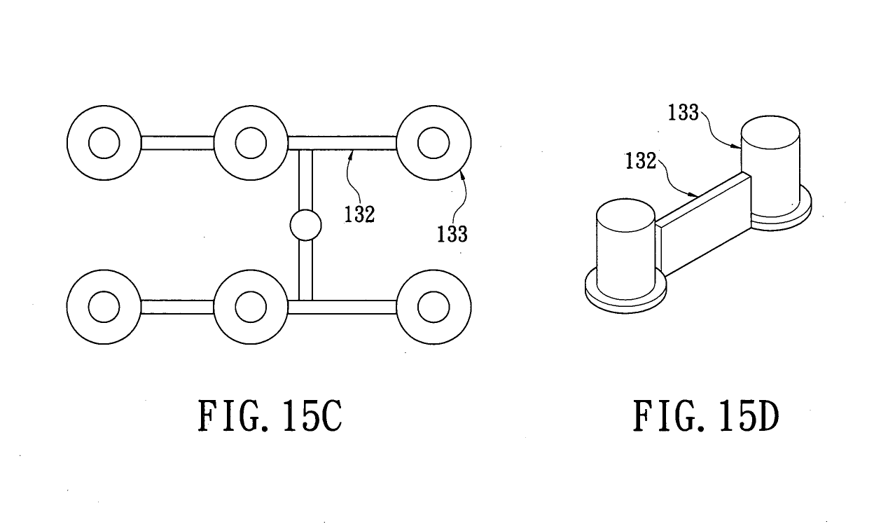

Referring to FIGS. 15A to 15D, a plurality of structure strengthening bodies 13 can be fabricated such that each element 133 is joined to the other elements 133 through a web connecting structure. Such structure could be the result, for example, of webs 132 existent when the strengthening elements 133 are stamped or pressed from a sheet of metal or other suitable material. Having the connecting web structure 132 insures that each strengthening element 133 is held securely in geometrical relationship to the other elements 133, such that when the elements 133 are placed onto a casing of the vapor chamber all the elements are easily and at once aligned. Furthermore by nature of the stamping fabrication process the strengthening elements 133 are hollow or open at one end. These hollow or open ends can be aligned to bumps or protrusions in the casing, for example as shown for casing 102 in the Figure.

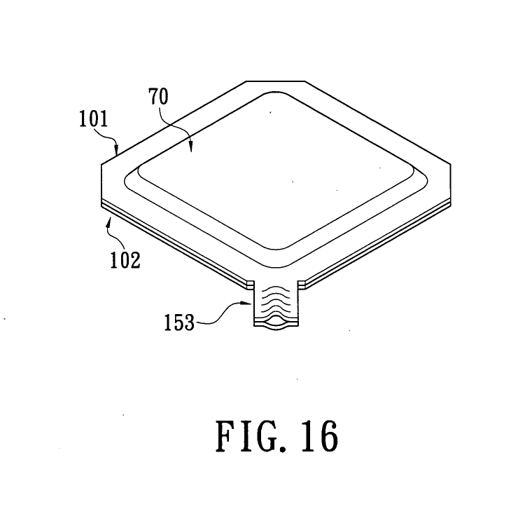

Referring to FIG. 16, there is provided a vapor chamber having a filling orifice 153 that is integrally formed by the casing 101 and 102, either wholly within the casing material or including the joint between the upper casing 101 and lower casing 102. This is in contrast to the vapor chamber of FIGS. 2 through 5, where there is provided a separate filling pipe 15 that is affixed to and between the casing. Because the rate of evacuating the chamber (pumping away the air) and charging the chamber with the working fluid is directly related to the size of the filling orifice (pipe, slot or other) it is advantageous to provide as large a filling orifice as possible. The filling orifice 153 can practically be larger by forming the orifice integrally with the casing 101 and 102 versus by inserting a filling pipe, since the orifice shape can become an elongated slot or similar shape and its cross-section area quite large without extending past the external plane of either the upper casing 101 or lower casing 102. Furthermore an integral filling orifice 153 reduces the need for a separate filling pipe and simplifies the assembly process of the vapor chamber since there is no joining or affixing of the separate filling pipe. Although the filling orifice 153 is shown protruding from a corner of the vapor chamber in FIG. 16, it is to be understood that the filling orifice could be located anywhere along the periphery of the casing. It is to be further understood that during the fabrication process once the vapor chamber is filled with the working fluid the filling orifice 153 would be sealed shut.

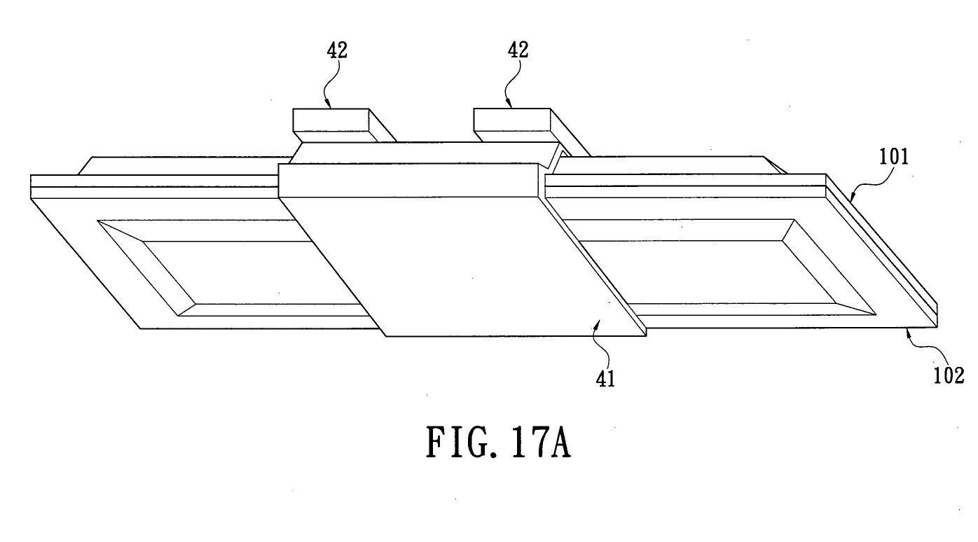

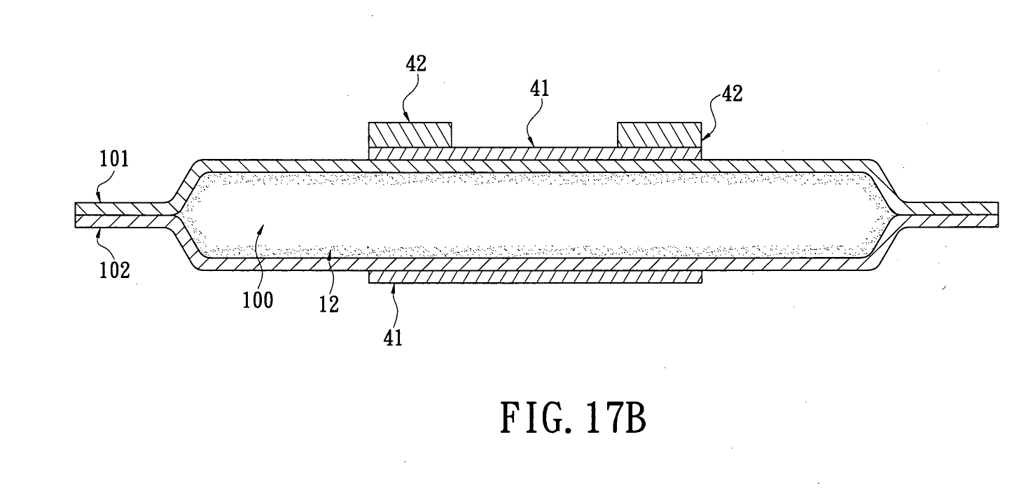

Referring to FIGS. 17A to 17B, there is provided a vapor chamber having a structural support member 41 or members that extend around a periphery of the vapor chamber. These peripheral structural support members 41 are made of a material that is stiffer and stronger than the material used for the vapor chamber casings 101 and 102. The structural support member(s) 41 may be tightly joined to one or more of the vapor chamber casings 101 or 102 or alternatively may be just loosely contacting the casings. The structural support member 41 can itself have further structural elements 42 that are yet again stronger than the peripheral element 41. These elements 42 can be structural members such as beams or other sections that, taken together with the structural supporting elements 41 can support a high applied load or force without deforming or crushing the vapor chamber casing 10. Ideally the materials used to fabricate elements 41 and 42 will be strong, lightweight in comparison to their strength, and have relatively good thermal conductivity, such as metals like aluminum or steel.

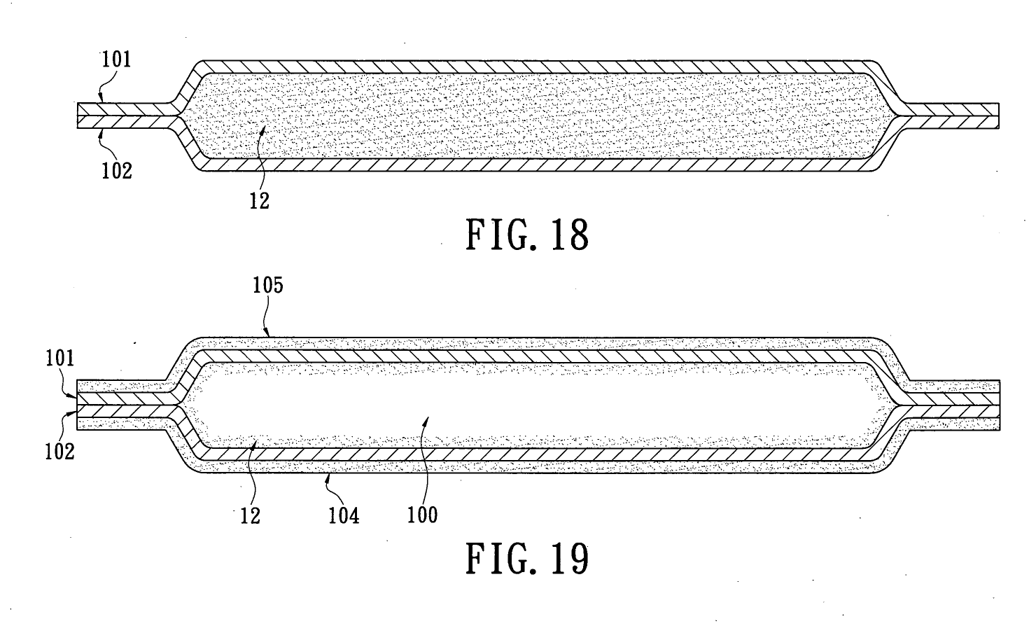

Referring to FIG. 18, a vapor chamber is provided where the wick material(s) 12 completely fill the vacuum chamber 100 between the casings 101 and 102. In this case the wick material itself is able to strengthen the vapor chamber and allow it to support a much higher applied load or force than a vapor chamber with some amount of empty, unfilled space in the vacuum chamber 100.

Referring to FIG. 19, a vapor chamber is provided that utilizes a clad or similar multi-layer material. More specifically the casings 101 and 102 are mated with a stronger material, 105 and 104, respectively, that impart overall strength to the combined structure. In the case of metal materials the preferred embodiment is to use pre-fabricated clad materials (metal sheets that are bonded by high pressure and temperature to form a durable bond between the material)—for example a copper material that will be used to form casings 101 and 102 can be clad with a steel material that will be used to form the structural strengthening materials 105 and 104, respectively. The structural cladding material will preferentially have high strength versus its weight and thickness and also will have relatively high thermal conductivity. The clad material is formed from at least one layer of metal and at least one layer of copper or copper-bearing alloys. Alternatively, the clad material is formed from at least one layer of ceramic material and at least one layer of metal material. It will also be able to be metallurgically joined to the casing material and be easily formed or fabricated into the geometric shapes required to form the vapor chamber. Other embodiments could include structural strengthening materials 104 and 105 that are joined to the casings 102 and 101, respectively, by other means including but not limited to diffusion bonding, soldering, brazing or adhesive joining.

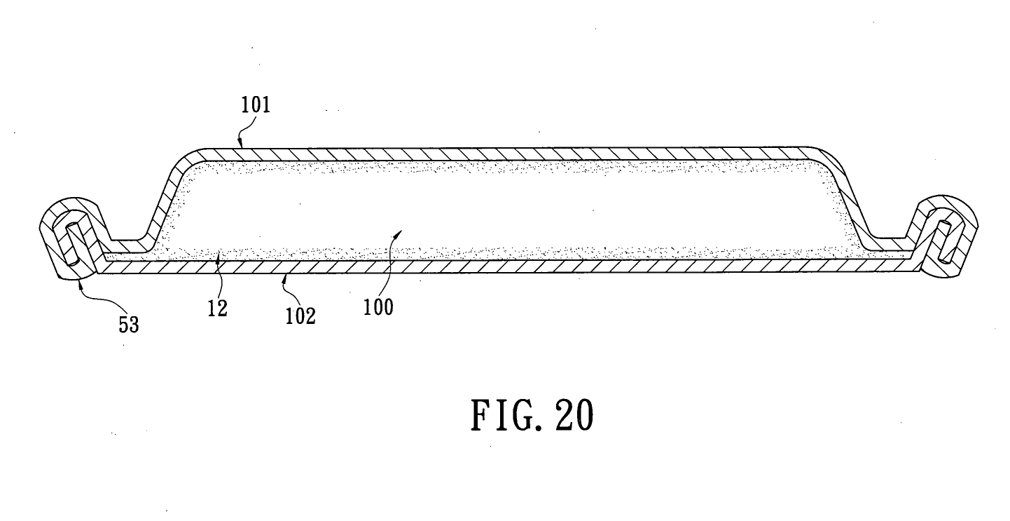

Referring to FIG. 20, a vapor chamber with seam-sealed edges is provided. In this case the casings 101 and 102 are designed such that there is sufficient material width along their periphery to be able to mechanically bend, curl and compress those casings 101 and 102 tightly together along their peripheral edge to form what is commonly referred to as a double seam seal 53. Formed properly a double seam seal is a strong, hermetic seal that is fully suitable for creating a vapor chamber. In some cases a separate sealing material (e.g. a polymer), not shown, can be placed between the peripheral edges of casings 101 and 102 to be double seam sealed whose purpose is to further insure that a hermetic seal is formed. The vapor chamber of FIG. 20 does not include a filling pipe, since the appropriate working fluid is introduced and the vacuum environment of the vapor chamber is created during the seam sealing operation by controlling the vacuum level under which the seam sealing occurs.

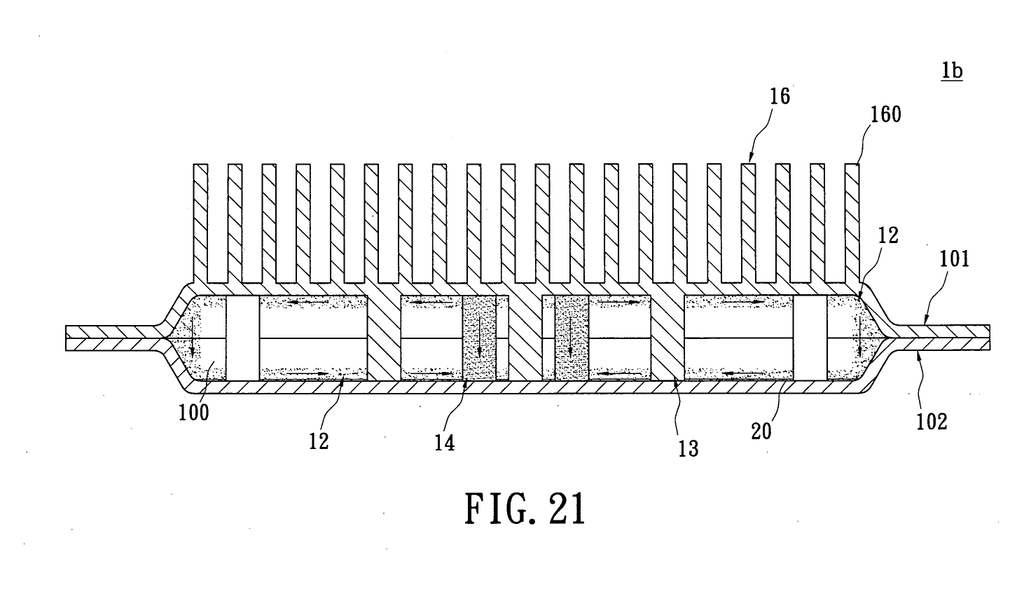

Referring to FIG. 21, a vapor chamber is provided with one or more cooling fins 160 or structures formed integrally in the exterior of the casing 10. In the figure a plurality of integral cooling fins 160 form an overall cooling structure or heat sink 16, which is likewise integral with the casing 10. Because the cooling fins 160 are integral with the casing 101 the heat transfer from the vapor chamber to the cooling fins is optimized. It should be noted in this example that structure strengthening bodies 13 can also be integrally fabricated with the interior of the casing 10. In other words, each heat-dissipating fin 160 and each structure strengthening body 13 are integrally formed on the external surface and the internal surface of the casing 10, respectively. A preferred method for making such a structure is metal injection molding. If a metal injection molding process is used it is further possible to directly integrate backflow accelerating structures 14 into the casing 10 by use of a second injection into the mold, referred to as a second shot, of a material that will be porous at the completion of the casing manufacturing process.

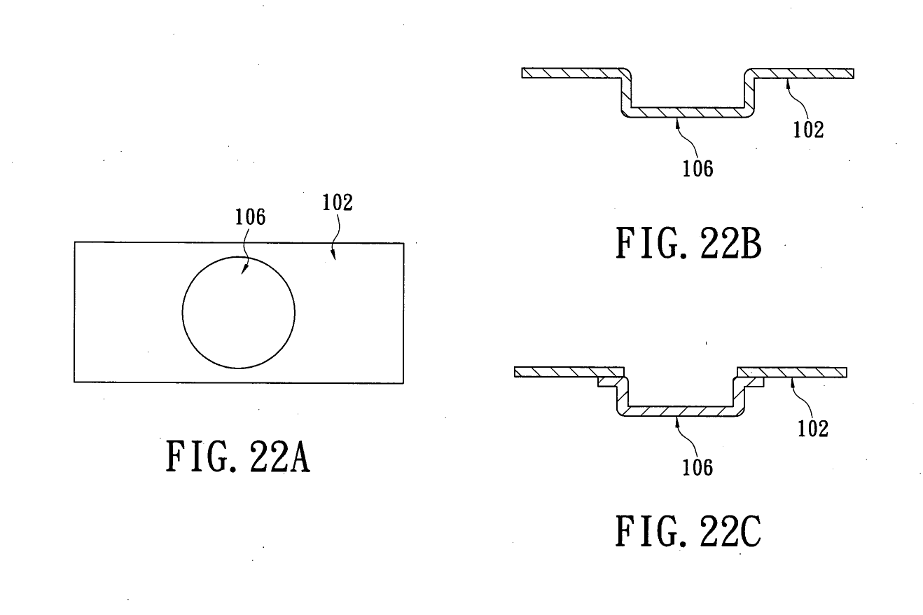

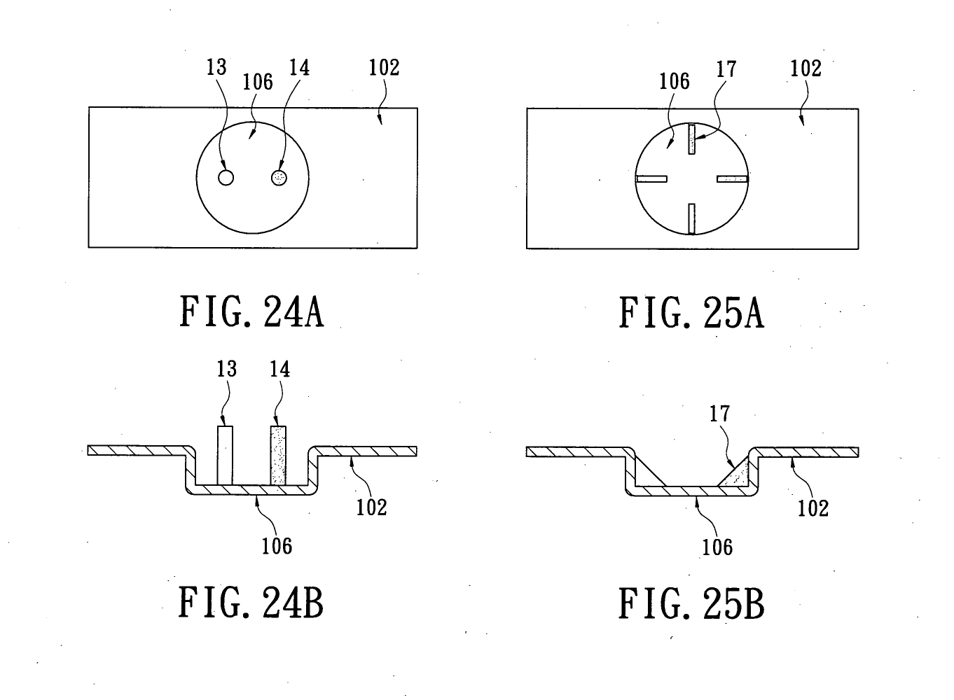

Referring to FIGS. 22A to 22C, a vapor chamber is provided with an outward protrusion or pedestal 106, such protrusion being formed integrally with the casing material, such as 102. The protrusion allows the vapor chamber to contact a heat source that is physically distant from the majority of the adjacent vapor chamber surface or plane. FIG. 24B also shows a vapor chamber with a similar protrusion 106, in this case such protrusion 106 being formed by a separate element that is attached to the casing (in FIG. 22C, the lower casing 102). The attachment method could be by soldering, brazing, adhesive joining or other methods known to those skilled in the art.

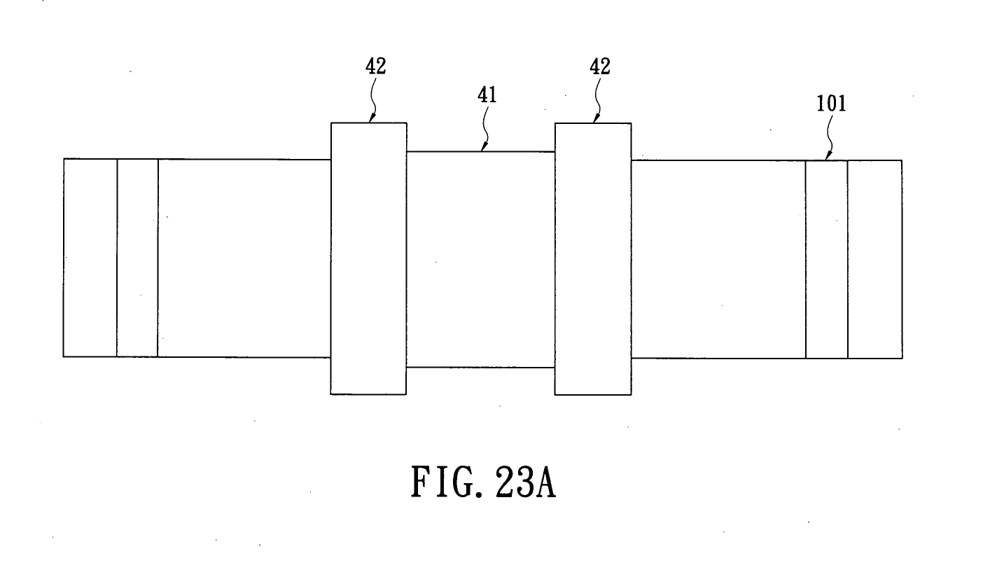

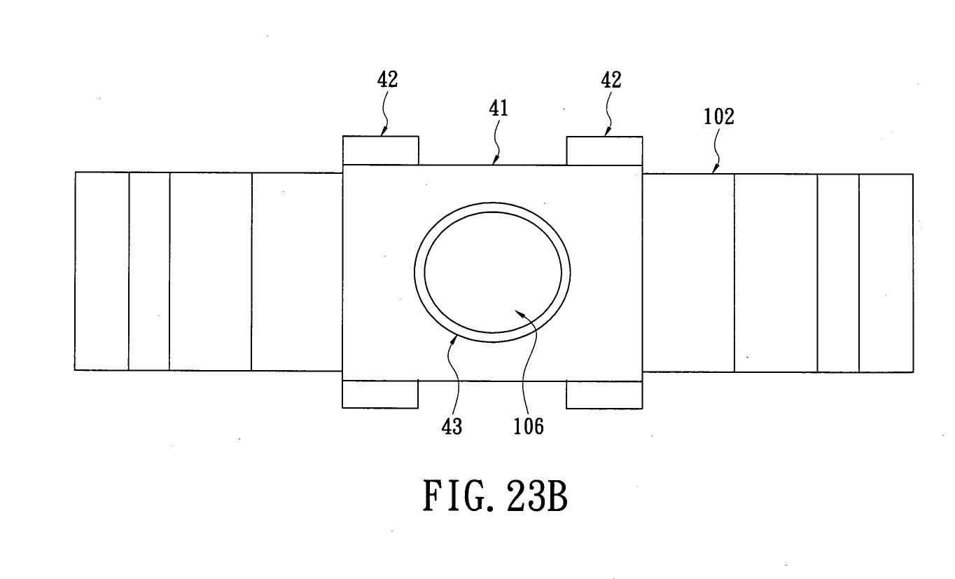

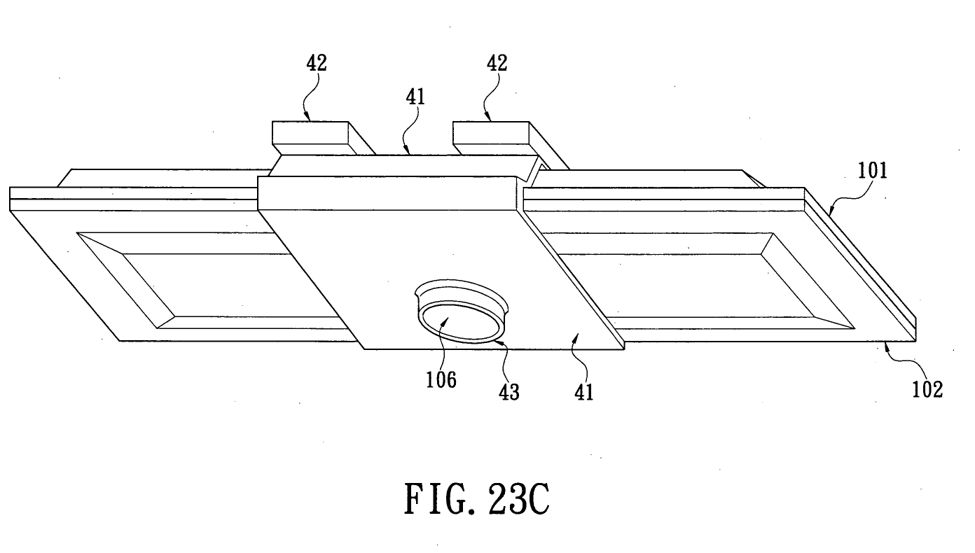

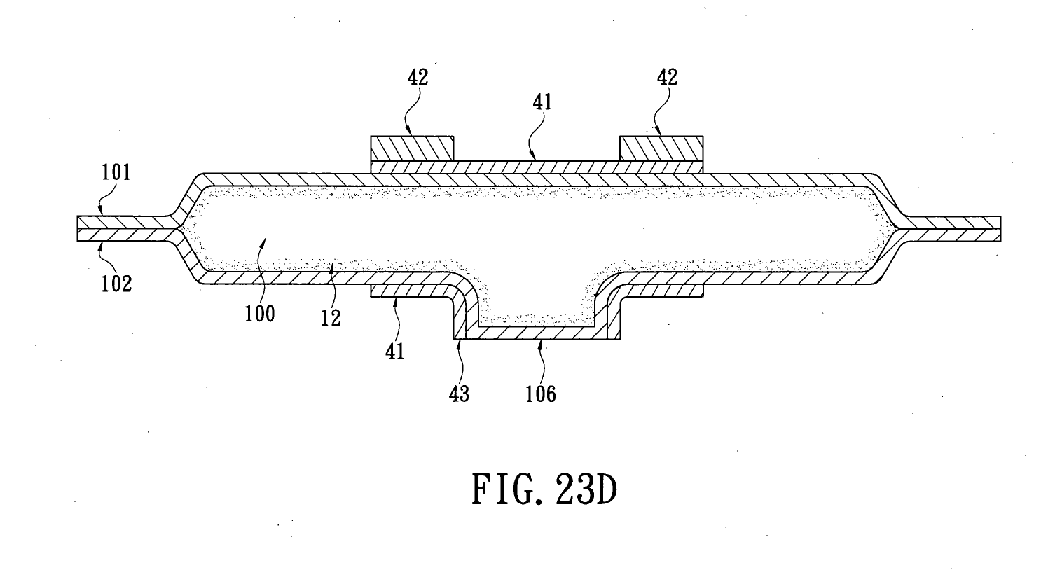

Referring to FIGS. 23A to 23D, a vapor chamber having a protrusion is provided, such protrusion supported by structural strengthening elements 41 that wrap around and surround certain areas of the vapor chamber, but primarily around the protrusion. In the embodiment shown in FIG. 23A, the structural strengthening element 41 generally supports a wide area of the vapor chamber casings 101 and 102, but also preferentially has a region 43 that surrounds and supports the protrusion 106. As shown in FIG. 23B the structural support region 43 encases a large portion of the periphery of the protrusion 106, but does not cover the surface that would be in contact with the heat source. In this fashion the protrusion 106 can be mechanically supported without the introduction of the strengthening element 41 material between the heat source, not shown, and the casing 102 that would impede the heat transfer from heat source to vapor chamber. In other embodiments where higher structural strength is required the strengthening element 41 could fully cover the periphery of the protrusion 106—with an attendant decrease in vapor chamber thermal performance. Furthermore additional structural strengthening elements 42 can be added to further increase the ability of the vapor chamber to support high applied loads or forces.

Referring to FIGS. 24A to 24B, a vapor chamber is provided having a protrusion 106, such protrusion supported by bodies in the form of bodies 13 or 14 that connect between the protrusion 106 in the casing 102 and the opposed casing 101 (not shown). These bodies 13 or 14 can be separate posts adjoined through any appropriate method to the casing 102 and/or 101 or they may also be integrally formed as part of the formation of the casing 102 or 101 as described elsewhere in this disclosure. Furthermore these bodies 13 and 14 may be of any geometric format and have attributes of any of the other structural strengthening elements previously described (e.g. having a wick structure external or internal to the bodies 13 or 14, the posts 14 being themselves made of a porous material, or having a secondary material incorporated in the bodies 13 such as by cladding to impart additional strength).

Referring to FIGS. 25A to 25B, a vapor chamber is provided having a protrusion 106, such protrusion supported by bodies in the form of ribs or buttresses 17 that connect between one surface of the protrusion 106 in the casing 102 and an adjacent surface of the protrusion 106. These ribs 17 can be separate elements adjoined through any appropriate method to the casing 102 or they may also be integrally formed as part of the formation of the casing 102 as described elsewhere in this disclosure (e.g. by metal injection molding or stamping). Furthermore these ribs 17 may be of any geometric format and have attributes of any of the other structural strengthening bodies previously described (e.g. having a wick structure external or internal to the ribs 17, the ribs 17 being themselves made of a porous material, or having a secondary material incorporated in the rib 17 such as by cladding to impart additional strength).

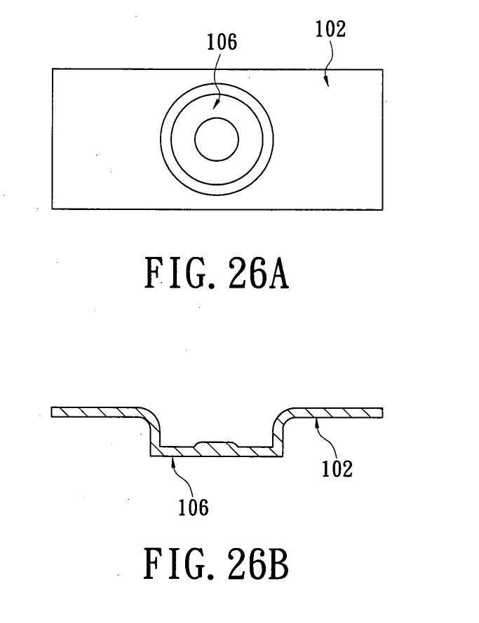

Referring to FIGS. 26A to 26B, a vapor chamber is provided having a protrusion 106, such protrusion strengthened by structural strengthening elements within the material of the protrusion in the form of areas of varying thickness to impart strength to the structure. It is well known that structural members with cross-sections of different areas and shapes can improve their strength.

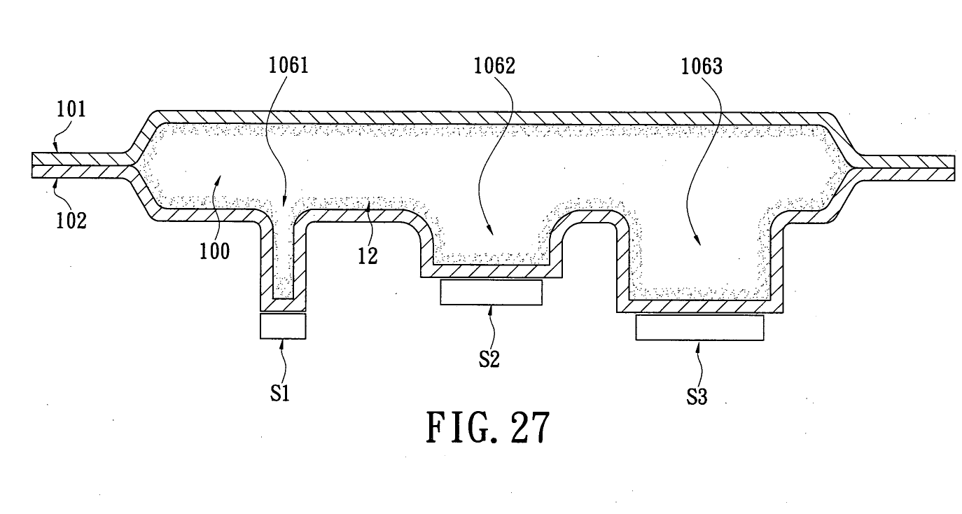

Referring to FIG. 27, a vapor chamber is provided having a plurality of protrusions depicted as 1061, 1062 and 1063, such protrusions on one or multiple levels or heights depending on the height of the heat sources S1, S2 or S3 to which they are applied. Furthermore these protrusions can each have a unique area or geometric shape as required for the best contact and heat transfer to their individual heat sources.

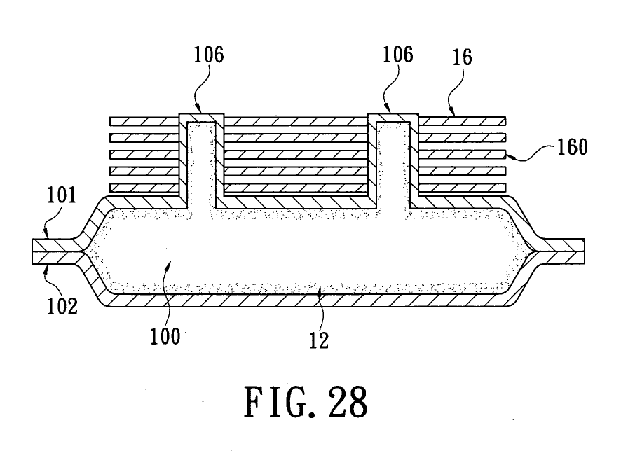

Referring to FIG. 28, a vapor chamber is provided having one or more protrusions 106, such protrusion(s) forming both a structural element and a heat transfer medium to which are attached one or more fins 160 whose purpose is to dissipate heat to the surrounding environment. Since a vapor chamber is an excellent heat spreader it is advantageous to use the structure of the vapor chamber to not only spread heat efficiently away from the heat source(s), but also to spread or transfer heat efficiently to the cooling environment. Often the heat is spread to the cooling environment through the use of a coolant fluid, such as air, that is flowed over extended surfaces or fins. Fin thermal efficiency is highly dependent on the geometry of the fin, its material thermal conductivity and the coolant flow characteristics across the fin. A long, thin fin heated at only one end transfers more heat where it is hotter near the heated end and progressively less heat towards the unheated end. For sufficiently long fins it can quite often be the case that a significant proportion of the total length of the fin located at the unheated end of the fin will transfer relatively little of the heat applied to the fin—in essence rendering a large portion of the fin structure practically useless. This situation can be rectified by applying heat in several locations along the length of the long fin, such that the fin length from heat source to unheated fin area is kept short. The configuration of the vapor chamber of FIG. 28 provides the improved condition for heat transfer to the environment by having protrusions 106 that insert heat to several locations along the long fins 160, keeping the effective unheated length of the fins short.

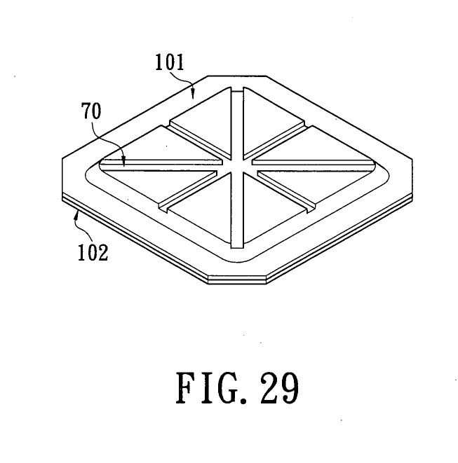

Referring to FIG. 29, a vapor chamber is provided that includes one or more channels on one or more of its exterior surfaces. Such channels have been found to promote the easy flow of viscous thermal interface materials (such as thermal greases or phase change materials) and to allow a heat dissipating structure (such as the provided vapor chamber) to minimize the thickness of the thermal interface material between that heat dissipating structure and the heat source. By minimizing the thermal interface material thickness, the thermal resistance between the heat source and heat dissipating structure is likewise minimized - making the heat transfer from the heat source to the heat dissipating structure and ultimately to the environment much more efficient. Channels or grooves as shown can be placed on one or several surfaces that contact with thermal interface materials.

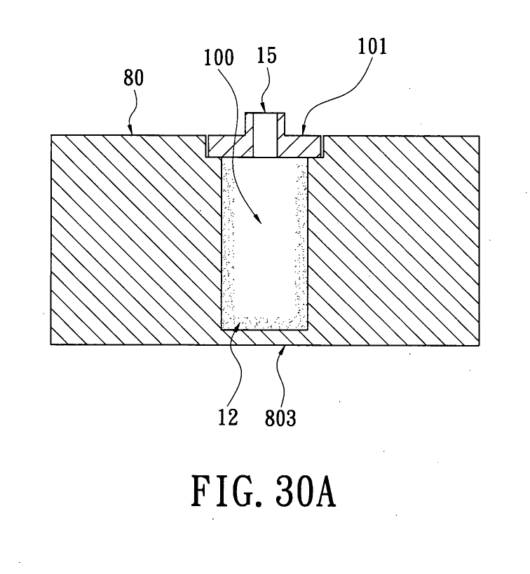

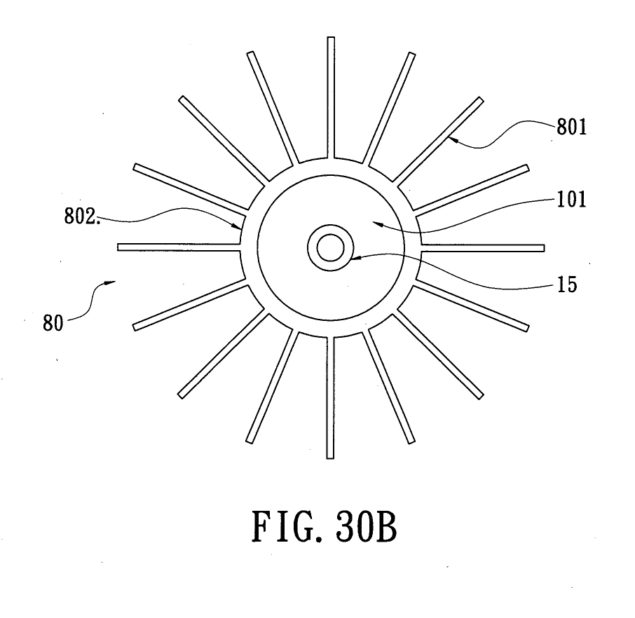

Referring to FIGS. 30A to 30B, an extruded heat sink 80 with radial fins 801 is provided, such heat sink body 802 including a vapor chamber and one or more surfaces 803 for heat input from a heat source (not shown). The heat sink body has a vacuum chamber 100 formed within it (e.g. by drilling or boring), including a wick 12. The vacuum chamber 100 is sealed with a casing or cover 101. That casing 101 has within it a filling tube 15 used for evacuating the air from the chamber 100 and filling it with a working fluid 20 as previously described elsewhere. The heat sink 80 of FIG. 30 has fins 801 that extend in a radial fashion from the heat sink body 802—the body with included fins formed by extrusion in an axial direction. The advantage of using an extruded heat sink is that it is generally the lowest cost method to make such a complex structure of body and fins. Incorporating a vapor chamber integrally inside the body of the heat sink optimizes the heat transfer from the heat source, through the heat input area 803 and into the fins 801 for transfer to the environment. Prior art has described placing a separately fabricated and fully enclosed vapor chamber into an extruded heat sink—but that prior art is less advantageous because there will be a thermal resistance between the separately fabricated vapor chamber casing and the heat sink body. Integrally incorporating a vapor chamber directly into an extruded heat sink body 102 as shown in FIG. 30 overcomes the prior art disadvantages and maximizes the heat transfer capability of the overall structure.

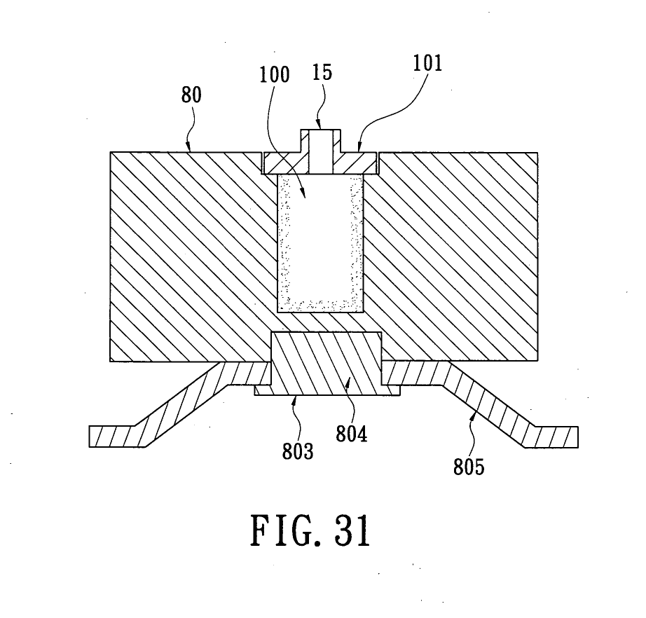

Referring to FIG. 31, a vapor chamber formed in the body 802 of an extruded heat sink 80 and also including a mounting bracket 805 and an element 804 that attaches said bracket to the heat sink is provided. In many cases it is desirable to include some mounting hardware with the heat sink that allows the heat sink to be readily affixed in its application (e.g. mounting the heat sink 80 by use of the mounting bracket 805 to a printed circuit board in a computer (not shown) so that the heat sink's heat input area 803 is in contact with the heat source to be cooled, such as a CPU chip). Although an element 804 for mounting the bracket 805 is shown central to the bracket 805 and heat sink 80, it will be understood by those skilled in the art that other mounting elements (e.g. screws) located in other areas can be used to affix the mounting bracket 805 to the heat sink 80.

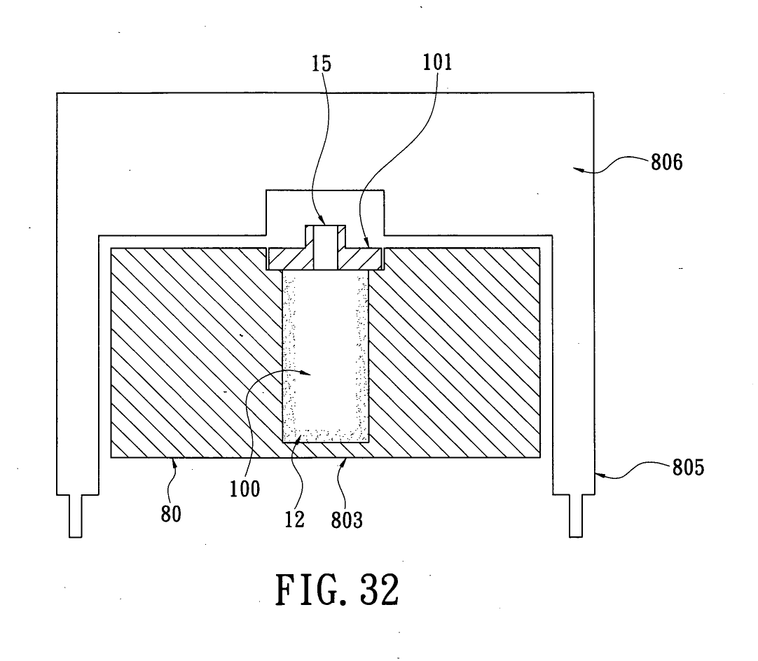

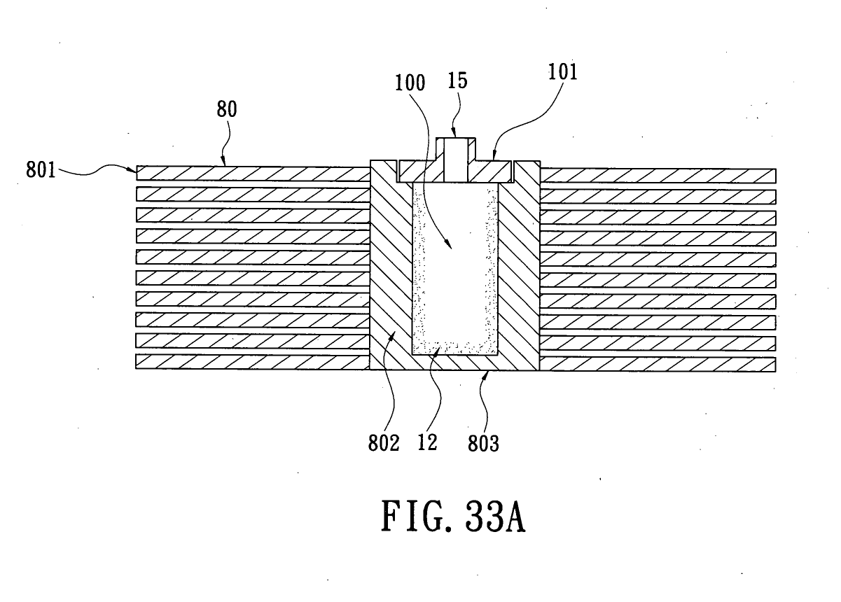

Referring to FIG. 32, an extruded heat sink 80 is provided which includes a vapor chamber in the body of the heat sink 802 and to which is attached a fan 806 and a fan housing and mounting structure 805. It is often desirable for a heat sink for convective air cooling to be provided with its own fan if the heat dissipation of the heat source is sufficiently high. The structure of FIG. 32 provides for this desirable case by incorporating the fan 806 and the fan housing and mounting structure 805.

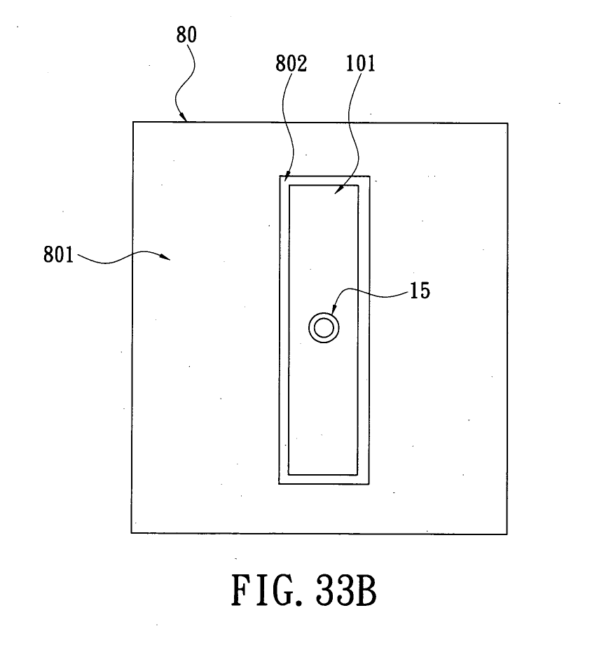

Referring to FIGS. 33A to 33B, a linear extruded heat sink 80 is provided with linear fins 801, such heat sink including the formation of a vapor chamber in the body 802 of the heat sink. In contrast to the heat sink of FIG. 30, the heat sink of FIG. 33 is extruded in a linear fashion along an axis such that the fins are aligned with the extrusion axis. In this case the vacuum chamber 100 will be rectilinear in shape and likewise the casing 101 to enclose and seal the vacuum chamber will also be generally rectilinear in shape.

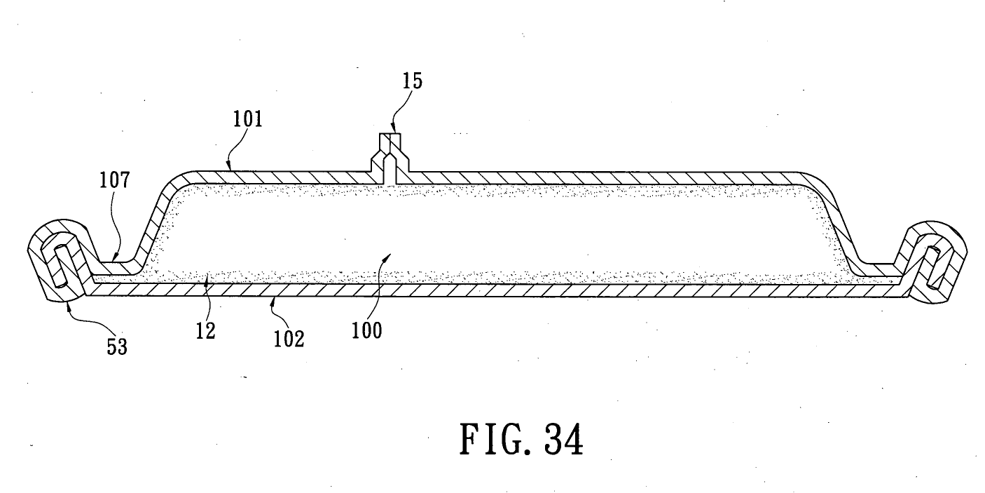

Referring to FIG. 34, a vapor chamber with seam-sealed edges 53 and a filling pipe or hole 15 is provided. In this case the casings 101 and 102 are designed such that there is sufficient material width along their periphery to be able to mechanically bend, curl and compress those casings 101 and 102 tightly together along their peripheral edge to form what is commonly referred to as a double seam seal 53. Formed properly a double seam seal is a strong, hermetic seal that is fully suitable for creating a vapor chamber. In some cases a separate sealing material (e.g. a polymer), not shown, can be placed between the peripheral edges of casings 101 and 102 to be double seam sealed whose purpose is to further insure that a hermetic seal is formed. The vapor chamber of FIG. 34 includes a filling pipe 15 for evacuating the chamber and introducing the working fluid into the chamber. The filling pipe 15 can be separately fabricated and joined to an appropriate hole or flange in the casing (as previously described for other embodiments)—although for the case of the seam sealed vapor chamber the location of the filling pipe 15 must necessarily not be in the peripheral edge that will be formed into the seam seal. In a preferred embodiment, the filling pipe 15 is as shown in FIG. 34 where it is integrally incorporated as part of the casing 101—such as by stamping and forming a section of the casing 101 to have a perforated hole through the casing and a flange of sufficient geometry to form an extended flange or pipe-like structure 15 for the purposes of evacuating and filling the chamber. After the chamber is evacuated and filled with the working fluid 20 the fill pipe 15 is closed and sealed.

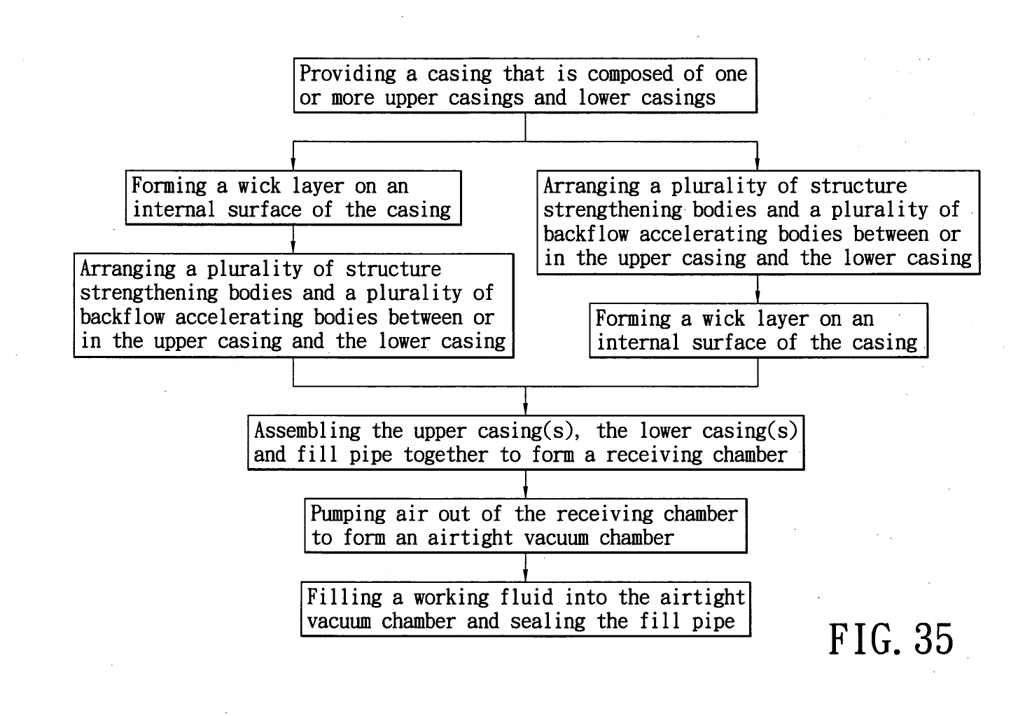

Referring to FIG. 35, the present invention provides a method for manufacturing a vapor chamber structure of one embodiment of the present invention. The method comprises providing a casing 10 that is composed of an upper casing 101 and a lower casing 102; forming a wick layer 12 on an internal surface of the casing 10 and then respectively arranging a plurality of structure strengthening bodies 13 and a plurality of backflow accelerating bodies 14 between the upper casing 101 and the lower casing 102.

The method further comprises assembling the upper casing 101 and the lower casing 102 together to form a receiving chamber; pumping away air from the receiving chamber to form an airtight vacuum chamber 100 and then filling a working fluid 20 into the airtight vacuum chamber 100 and sealing the casing 10.

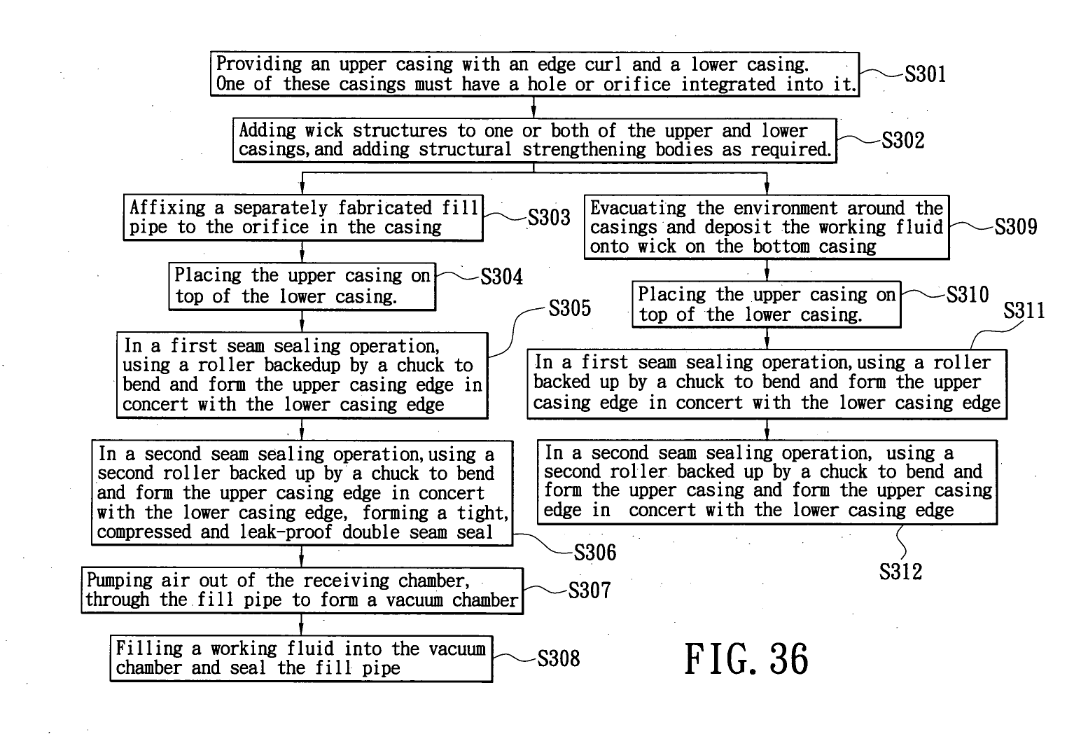

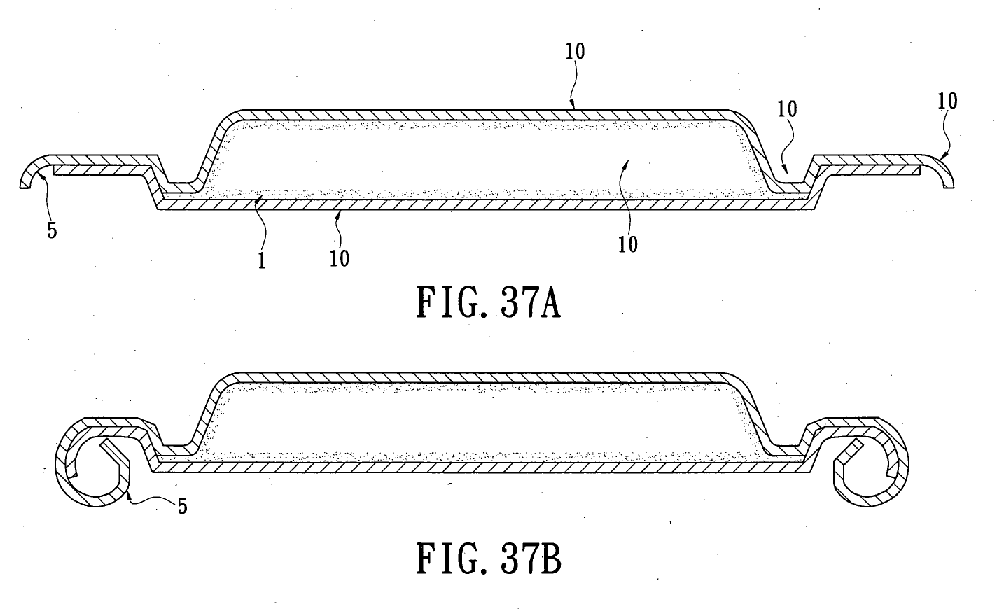

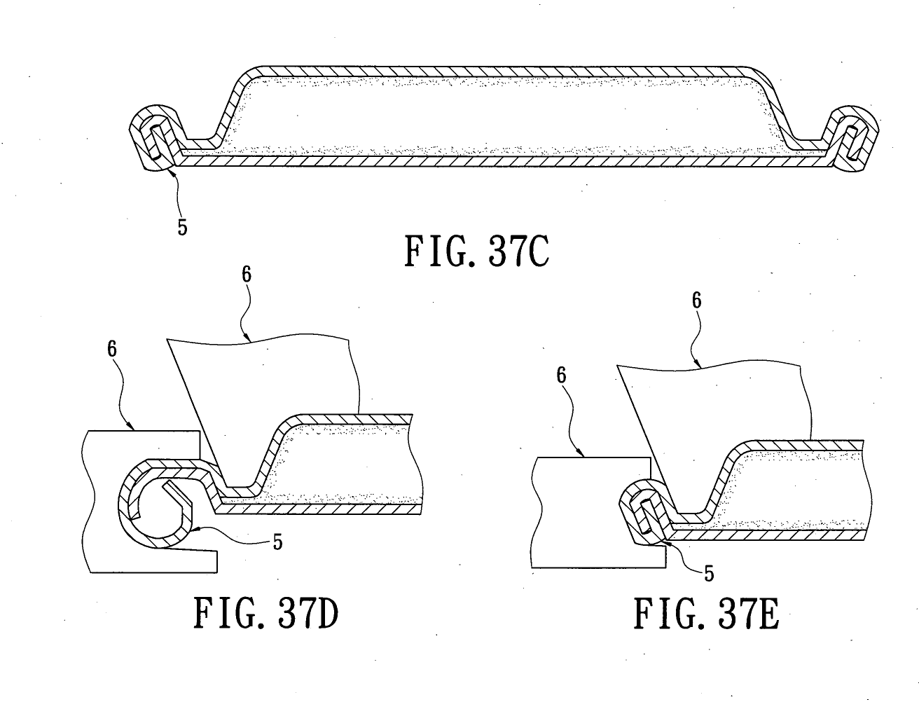

Referring to FIG. 36, a flowchart is provided of a method for manufacturing a vapor chamber whose edges are seam sealed, and referring to FIGS. 37A to 37E, a series of cross-section, schematic drawings is provided showing the sequence of steps in the manufacturing of a vapor chamber whose edges are seam sealed. In step S301, Providing an upper casing with an edge curl and a lower casing is produced. In this step there is provided a casing 101 with a chuck groove 107 and an edge curl 109. In step S302, adding wick layer on internal surfaces of the upper and lowing casing; in step S303, affixing a fill pipe on the casing; in step S304, placing the upper casing on top of the lower casing and then in step S305, the edge of the upper casing is bent by a chuck. In this step, the edge curl 109 may or may not have some separate edge sealing material 51 applied to it that can aid in ensuring the seam seal area is fully sealed. This material 51 can be of various compositions although polymer materials such as epoxies are typical. In a first step the top casing 101 is brought into contact with the bottom casing 102 such that the edge curls 109 are aligned outside the periphery of the edges the bottom casing 102 and the top casing 101 chuck groove 107 is aligned and fits inside the wall of the bottom casing 102. In step S306, a forming anvil or chuck 60 is fit into the chuck groove 107. The purpose of said chuck 60 is to support and provide an anvil against which the casings can be deformed and sealed. Then there occurs a first sealing operation during which a first sealing die or roller 61 is brought in contact with the peripheral edge or curl area 109 of the top casing 101. During this step S306 either the whole vapor chamber is rotated or the roller 61 is moved so that there is a relative motion of the roller 61 all around the periphery of the vapor chamber. The shape of the roller 61 is such that as it presses inwards on the periphery of the casing 101 the end curl 109 and a portion of the periphery of the casing 102 are formed and curled loosely together, completing what is commonly referred to as the first seam sealing operation. In step S306 a second die or roller 62 with a shape different from the first roller 61 and backed up by a chuck 60 traverses along the periphery of the previously formed loose seam seal. The second roller 62 bends and forms the upper casing 101 periphery in concert with the lower casing 102 periphery forming a tight, compressed and leak-proof double seam seal in what is commonly referred to as the second seam sealing operation. Then step S307, pumping air out of the casing is produced and the final step S308 is used to fill working fluid into the chamber and then seal the pipe. Alternatively, after S302, S309 can be processed. In S309, evacuating the environment around the casing and deposit the working fluid onto wick on the bottom casing is produced. Then, S310 is produced to place the upper casing on top of the low casing. In step S311, the edge of the upper casing is bent by a chuck and then a second die or roller 62 with a shape different from the first roller 61 and backed up by a chuck 60 traverses along the periphery of the previously formed loose seam seal in S312.

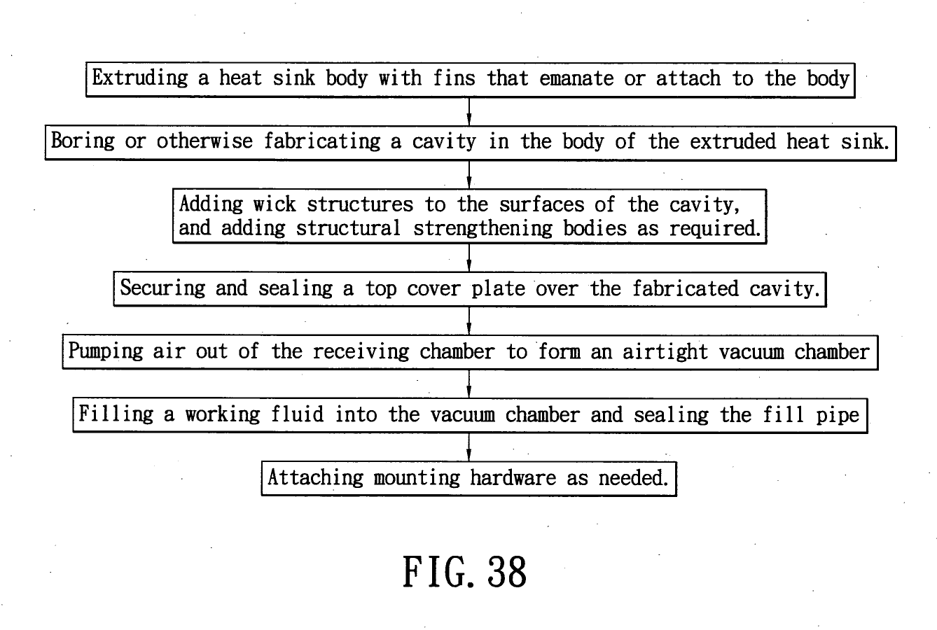

Referring to FIG. 38, a flowchart is provided of a method for manufacturing a vapor chamber from an extruded heat sink body with one or more attached fins.

In conclusion, the vapor chamber structure of the present invention has capabilities as a structure strengthening function and a backflow accelerating function due to the usage of the structure strengthening bodies 13 and the backflow accelerating bodies 14. Therefore, the present invention can maintain the completeness of the vapor chamber structure and increase the backflow velocity of the working fluid 20 due to the match of the structure strengthening bodies 13 and backflow accelerating bodies 14. Because the backflow velocity of the working fluid 20 is increased, the heat-transmitting efficiency is increased.

Although the present invention has been described with reference to the preferred best methods thereof, it will be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A vapor chamber structure, comprising:
a casing having an airtight vacuum chamber;
a working fluid filled into the airtight vacuum chamber;
a wick layer formed on an internal surface of the airtight vacuum chamber; and
one or more structure strengthening bodies supporting inside the casing.

2. The vapor chamber structure as claimed in claim 1, wherein the casing is composed of an upper casing and a lower casing that mates with the upper casing.

3. The vapor chamber structure as claimed in claim 1, wherein the casing has at least one hollow protrusion respectively contacted with a plurality of cooling fins.

4. The vapor chamber structure as claimed in claim 2, wherein the casing has a contact surface between the upper casing and the lower casing, and the contact surface has a predetermined width.

5. The vapor chamber structure as claimed in claim 2, wherein each structure strengthening body is arranged between the upper casing and the lower casing.

6. The vapor chamber structure as claimed in claim 1, wherein the casing has one or more hollow protrusions, each contacted with a heat-generating source.

7. The vapor chamber structure as claimed in claim 6, wherein each hollow protrusion extends to a predetermined length.

8. The vapor chamber structure as claimed in claim 7, wherein each hollow protrusion has predetermined shape and size.

9. The vapor chamber structure as claimed in claim 6, wherein each hollow protrusion is fabricated separately and joined to the vapor chamber casing.

10. The vapor chamber structure as claimed in claim 9, wherein each hollow protrusion is fabricated from a material that is physically stronger than the vapor chamber casing material.

11. The vapor chamber structure as claimed in claim 1, further comprising a filling pipe, wherein a contact surface between the casing and the filling pipe has a length larger than a double length of a diameter of the filling pipe.

12. The vapor chamber structure as claimed in claim 1, wherein the casing has a joint opening for communicating the filling pipe with the airtight vacuum chamber.

13. The vapor chamber structure as claimed in claim 6, wherein at least one structure strengthening body is disposed inside at least one of the protrusions.

14. The vapor chamber structure as claimed in claim 13, wherein the structure strengthening bodies are affixed within the interior surface of the protrusions and contacting the opposing portion of the casing.

15. The vapor chamber structure as claimed in claim 14, wherein at least one backflow accelerating elements are affixed to the protrusions.

16. The vapor chamber structure as claimed in claim 6, wherein the protrusion has structure strengthening bodies affixed with the interior portion of the protrusion and contacting the bottom and adjacent wall of the protrusion.

17. The vapor chamber structure as claimed in claim 16, wherein the protrusion has backflow accelerating elements affixed with the interior portion of the protrusion and contacting the bottom and adjacent wall of the protrusion.

18. The vapor chamber structure as claimed in claim 6, wherein the material forming the protrusion has varying thickness to provide extra strength to the protrusion.

19. The vapor chamber structure as claimed in claim 18, wherein the protrusion has backflow accelerating elements affixed with the interior portion of the protrusion wherein the backflow accelerating elements are affixed within the interior surface of the protrusions and contacting the opposing portion of the casing.

20. The vapor chamber structure as claimed in claim 1, wherein the structure strengthening bodies are in the form of chamfered posts arranged in the airtight vacuum chamber.

21. The vapor chamber structure as claimed in claim 1, wherein the structure strengthening bodies are coated by a coating layer, wherein the coating layer promotes the adhesion between the structure strengthening body and the casing.

22. The vapor chamber structure as claimed in claim 1, wherein the casing is coated by a coating layer, wherein the coating layer promotes the adhesion between the structure strengthening bodies and the casing.

23. The vapor chamber structure as claimed in claim 1, wherein each structure strengthening body is formed by combining two portions of the structure strengthening body.

24. The vapor chamber structure as claimed in claim 1, wherein at least one structure strengthening body is affixed within indents in the casing that provide for alignment.

25. The vapor chamber structure as claimed in claim 1, wherein at least one structure strengthening body is affixed over bumps in the casing that provide for alignment.

26. The vapor chamber structure as claimed in claim 1, further comprising a plurality of strengthening elements, wherein at least one tree is connected between each of two or more strengthening elements and each strengthening element is in a solid or porous form.

27. The vapor chamber structure as claimed in claim 1, further comprising a filling pipe communicated with the airtight vacuum chamber, wherein the filling pipe has an opening side formed on one side thereof and a closed side formed on the other side thereof.

28. The vapor chamber structure as claimed in claim 1, further comprising a filling orifice communicated with the airtight vacuum chamber, wherein the filling orifice has an opening side formed on one side thereof and a closed side formed on the other side thereof, and which is integrally formed with the casing.

29. The vapor chamber structure as claimed in claim 28, wherein the cross-sectional area of the filling orifice is larger than Pi multiplied times the square of one half the thickness of the vapor chamber.

30. The vapor chamber structure as claimed in claim 1, further comprising a filling orifice communicated with the airtight vacuum chamber, wherein the filling orifice has an opening side formed on one side thereof and a closed side formed on the other side thereof, and which is integrally formed by the casing and the casing joint.

31. The vapor chamber structure as claimed in claim 30, wherein the cross-sectional area of the filling orifice is larger than Pi multiplied times the square of one half the thickness of the vapor chamber.

32. The vapor chamber structure as claimed in claim 1, wherein the wick layer is made of powders via a sintering method.

33. The vapor chamber structure as claimed in claim 32, wherein the powders are ceramic, copper, nickel, brass, bronze or steel powders.

34. The vapor chamber structure as claimed in claim 1, wherein each structure strengthening body is a solid post.

35. The vapor chamber structure as claimed in claim 34, wherein the solid post is a ceramic, copper, nickel, brass, bronze or steel post.

36. The vapor chamber structure as claimed in claim 1, wherein each structure strengthening body is composed of a solid post and a wick layer covered circumferentially on an external surface of the solid post.

37. The vapor chamber structure as claimed in claim 36, wherein the wick layer is formed by metal or ceramic materials.

38. The vapor chamber structure as claimed in claim 37, wherein the wick layer is formed of sintered powder.

39. The vapor chamber structure as claimed in claim 37, wherein the wick layer is formed of wire meshing.

40. The vapor chamber structure as claimed in claim 1, wherein each structure strengthening body is arranged inside the airtight vacuum chamber and has slits or channels in the post surface.

41. The vapor chamber structure as claimed in claim 1, wherein the structure strengthening bodies are concentrated in a center position of the airtight vacuum chamber.

42. The vapor chamber structure as claimed in claim 1, wherein the structure strengthening bodies are integrally formed with the casing.

43. The vapor chamber structure as claimed in claim 42, wherein the structure strengthening bodies are created by stamping and forming portions of the casing into such bodies.

44. The vapor chamber structure as claimed in claim 42, wherein the structure strengthening bodies are integrally formed with the casing through a powder manufacturing process.

45. The vapor chamber structure as claimed in claim 44, wherein the powder manufacturing process comprises an injection molding process followed by sintering.

46. The vapor chamber structure as claimed in claim 44, wherein the powder manufacturing process comprises a powder pressing process followed by sintering.

47. The vapor chamber structure as claimed in claim 1, wherein each structure strengthening body is composed of a wick and a solid layer covered circumferentially on an external surface of the wick.

48. The vapor chamber structure as claimed in claim 47, wherein the wick layer is formed by metal or ceramic materials.

49. The vapor chamber structure as claimed in claim 48, wherein the materials comprise sintered powders.

50. The vapor chamber structure as claimed in claim 48, wherein the wick is comprised of wire mesh.

51. The vapor chamber structure as claimed in claim 47, wherein the solid layer has slits or channels on the surface thereof.

52. The vapor chamber structure as claimed in claim 1, further comprising a plurality of heat-dissipating fins integrally formed with an external portion of the casing.

53. The vapor chamber structure as claimed in claim 1, further comprising at least one structural strengthening element extending around at least a portion of the periphery of the vapor chamber.

54. The vapor chamber structure as claimed in claim 53, wherein each structural strengthening element is affixed to the casing.

55. The vapor chamber structure as claimed in claim 53, wherein each structural strengthening element is not permanently affixed to the casing.

56. The vapor chamber structure as claimed in claim 53, wherein each structural strengthening element is comprised of at least one material that is stronger than the casing material.

57. The vapor chamber structure as claimed in claim 6, further comprising at least one structural strengthening element extending around at least a portion of the periphery of the vapor chamber.

58. The vapor chamber structure as claimed in claim 57, wherein each structural strengthening element is affixed to the casing.

59. The vapor chamber structure as claimed in claim 57, wherein each structural strengthening element is not permanently affixed to the casing.

60. The vapor chamber structure as claimed in claim 57, wherein the structural strengthening element is comprised of at least one material that is stronger than the casing material.

61. The vapor chamber structure as claimed in claim 57, wherein the structural strengthening element does not cover the surface of the protrusion that is in contact with the heat source.

62. The vapor chamber structure as claimed in claim 1, wherein the vacuum space is completely filled by wick material, such wick material attached to the opposing interior surfaces of the casing and serving to also provide structural strength to the vapor chamber.

63. The vapor chamber structure as claimed in claim 1, wherein the casing is comprised of a multilayer material, with one layer being significantly stronger than the layer that forms the surface of the casing facing the interior of the vapor chamber.

64. The vapor chamber as claimed in claim 63, wherein the multilayer casing material is formed by a cladding process with a clad material.

65. The vapor chamber as claimed in claim 64, wherein the clad material is formed from at least one layer of metal and at least one layer of copper or copper-bearing alloys.

66. The vapor chamber as claimed in claim 64, wherein the clad material is formed from at least one layer of ceramic material and at least one layer of metal material.

67. The vapor chamber as claimed in claim 63, wherein the multilayer casing material is formed by affixing a plurality of material layers together through a joining process such as diffusion bonding, soldering, brazing or adhesive joining.

68. A method for manufacturing a vapor chamber structure, comprising:
providing a casing that is composed of at least one upper casings and at least one lower casings;
forming a wick layer on an internal surface of the casing; respectively arranging one or more structure strengthening bodies supporting the casing;
assembling the upper casing and the lower casing together to form a receiving chamber; and
pumping away air from the receiving chamber to form an airtight vacuum chamber for supporting the casing; and filling a working fluid into the airtight vacuum chamber and sealing the casing.

69. A vapor chamber structure, comprising:
a casing having an airtight vacuum chamber;
a working fluid filled into the airtight vacuum chamber;
a wick layer formed on an internal surface of the airtight vacuum chamber; and
one or more structure strengthening bodies supporting the casing; wherein a double seam seal is formed on peripheral edge of the casing.

70. The vapor chamber structure as claimed in claim 69, wherein the casing is composed of an upper casing and a lower casing that mates with the upper casing.

71. The vapor chamber structure as claimed in claim 70, wherein the casing has a contact surface between the upper casing and the lower casing, and the contact surface has a predetermined width.

72. The vapor chamber structure as claimed in claim 70, wherein each structure strengthening body is arranged between the upper casing and the lower casing.

73. The vapor chamber structure as claimed in claim 70, wherein the casing has one or more hollow protrusions, each contacted with a heat-generating source.

74. The vapor chamber structure as claimed in claim 73, wherein each hollow protrusion extends to a predetermined length.

75. The vapor chamber structure as claimed in claim 74, wherein each hollow protrusion has predetermined shape and size.

76. The vapor chamber structure as claimed in claim 73, wherein each hollow protrusion is fabricated separately and joined to the vapor chamber casing.

77. The vapor chamber structure as claimed in claim 76, wherein each hollow protrusion is fabricated from a material that is physically stronger than the vapor chamber casing material.

78. The vapor chamber structure as claimed in claim 73, wherein at least one structure strengthening body is disposed inside the protrusions.

79. The vapor chamber structure as claimed in claim 78, wherein the structure strengthening bodies are affixed within the interior surface of the protrusions and contacting the opposing portion of the casing.

80. The vapor chamber structure as claimed in claim 79, wherein at least one backflow accelerating elements are affixed to the protrusions.

81. The vapor chamber structure as claimed in claim 80, wherein the protrusion has backflow accelerating elements affixed with the interior portion of the protrusion and contacting the bottom and adjacent wall of the protrusion.

82. The vapor chamber structure as claimed in claim 73, wherein the protrusion has structure strengthening bodies affixed with the interior portion of the protrusion and contacting the bottom and adjacent wall of the protrusion.

83. The vapor chamber structure as claimed in claim 73, wherein the material forming the protrusion has varying thickness to provide extra strength to the protrusion.

84. The vapor chamber structure as claimed in claim 83, wherein the protrusion has backflow accelerating elements affixed with the interior portion of the protrusion wherein the backflow accelerating elements are affixed within the interior surface of the protrusions and contacting the opposing portion of the casing.

85. The vapor chamber structure as claimed in claim 73, further comprising one or more structural strengthening elements that extend around at least a portion of the periphery of the vapor chamber.

86. The vapor chamber structure as claimed in claim 85, wherein the structural strengthening element is affixed to the casing.

87. The vapor chamber structure as claimed in claim 85, wherein the structural strengthening element is not permanently affixed to the casing.

88. The vapor chamber structure as claimed in claim 85, wherein the structural strengthening element is comprised of a material or materials that are stronger than the casing material.

89. The vapor chamber structure as claimed in claim 85, wherein the structural strengthening element does not cover the surface of the protrusion that is in contact with the heat source.

90. The vapor chamber structure as claimed in claim 69, wherein the casing has at least one hollow protrusion respectively contacted with a plurality of cooling fins.

91. The vapor chamber structure as claimed in claim 69, wherein the structure strengthening bodies are in form of chamfered posts.

92. The vapor chamber structure as claimed in claim 69, wherein the structure strengthening bodies are coated, wherein such coating promotes the adhesion between the structure strengthening body and the casing.

93. The vapor chamber structure as claimed in claim 69, wherein the casing is coated, wherein such coating promotes the adhesion between the structure strengthening bodies and the casing.

94. The vapor chamber structure as claimed in claim 69, wherein each structure strengthening body is formed by combining two portions of the structure strengthening body.

95. The vapor chamber structure as claimed in claim 69, wherein one or more structure strengthening bodies is affixed within indents in the casing that provide for alignment.

96. The vapor chamber structure as claimed in claim 69, wherein at least one structure strengthening body is affixed over bumps in the casing that provide for alignment.

97. The vapor chamber structure as claimed in claim 69, wherein at least one tree is connected between each of two or more strengthening elements and each strengthening element is in a solid or porous form.

98. The vapor chamber structure as claimed in claim 69, further comprising a filling pipe communicated with the airtight vacuum chamber, wherein the filling pipe has an opening side formed on one side thereof and a closed side formed on the other side thereof.

99. The vapor chamber structure as claimed in claim 69, further comprising a filling orifice communicated with the airtight vacuum chamber, wherein the filling orifice has an opening side formed on one side thereof and a closed side formed on the other side thereof, and which is integrally formed with the casing.

100. The vapor chamber structure as claimed in claim 99, wherein the cross-sectional area of the filling orifice is larger than Pi multiplied times the square of one half the thickness of the vapor chamber.

101. The vapor chamber structure as claimed in claim 69, further comprising a filling orifice communicated with the airtight vacuum chamber, wherein the filling orifice has an opening side formed on one side thereof and a closed side formed on the other side thereof, and which is integrally formed by the casing and the casing joint.

102. The vapor chamber structure as claimed in claim 101, wherein the cross-sectional area of the filling orifice is larger than Pi multiplied times the square of one half the thickness of the vapor chamber.

103. The vapor chamber structure as claimed in claim 69, wherein the wick layer is made of powders via a sintering method.

104. The vapor chamber structure as claimed in claim 103, wherein the powders are ceramic, copper, nickel, brass, bronze or steel powders.

105. The vapor chamber structure as claimed in claim 69, wherein each structure strengthening body is a solid post.

106. The vapor chamber structure as claimed in claim 105, wherein the solid post is a ceramic, copper, nickel, bronze, brass or steel post.

107. The vapor chamber structure as claimed in claim 69, wherein each structure strengthening body is composed of a solid post and a wick layer covered circumferentially on an external surface of the solid post.

108. The vapor chamber structure as claimed in claim 107, wherein the wick layer is formed of ceramic or metal materials.

109. The vapor chamber structure as claimed in claim 108, wherein the wick layer is formed of sintered powder.

110. The vapor chamber structure as claimed in claim 108, wherein the wick layer is formed of wire meshing.

111. The vapor chamber structure as claimed in claim 69, wherein each structure strengthening body has slits or channels in the post surface.

112. The vapor chamber structure as claimed in claim 69, wherein the structure strengthening bodies are concentrated in a center position of the airtight vacuum chamber.

113. The vapor chamber structure as claimed in claim 69, wherein the structure strengthening bodies are integrally formed with the casing.

114. The vapor chamber structure as claimed in claim 113, wherein the structure strengthening bodies are created by stamping and forming portions of the casing into such bodies.

115. The vapor chamber structure as claimed in claim 113, wherein the structure strengthening bodies are integrally formed with the casing through a powder manufacturing process.

116. The vapor chamber structure as claimed in claim 115, wherein the powder manufacturing process comprises an injection molding process followed by sintering.

117. The vapor chamber structure as claimed in claim 115, wherein the powder manufacturing process comprises a powder pressing process followed by sintering.

118. The vapor chamber structure as claimed in claim 117 wherein each structure strengthening body is a powder post.

119. The vapor chamber structure as claimed in claim 69, wherein each structure strengthening body is composed of a wick and a solid layer covered circumferentially on an external surface of the wick.

120. The vapor chamber structure as claimed in claim 119, wherein the wick layer is formed by ceramic or metal materials.

121. The vapor chamber structure as claimed in claim 120, wherein the materials comprise sintered powder.

122. The vapor chamber structure as claimed in claim 120, wherein the materials comprise wire mesh.

123. The vapor chamber structure as claimed in claim 119, wherein the solid layer has slits or channels on surface thereof.

124. The vapor chamber structure as claimed in claim 69, further comprising a plurality of heat-dissipating fins integrally formed with an external portion of the casing.

125. The vapor chamber structure as claimed in claim 69, further comprising at least one structural strengthening element that extends around at least a portion of the periphery of the vapor chamber.

126. The vapor chamber structure as claimed in claim 125, wherein the structural strengthening element is affixed to the casing.

127. The vapor chamber structure as claimed in claim 125, wherein the structural strengthening element is not permanently affixed to the casing.

128. The vapor chamber structure as claimed in claim 125, wherein the structural strengthening element is comprised of at least one material that is stronger than the casing material.

129. The vapor chamber structure as claimed in claim 69, wherein the vacuum space is completely filled by wick material, such wick material attached to the opposing interior surfaces of the casing and serving to also provide structural strength to the vapor chamber.

130. The vapor chamber structure as claimed in claim 69, wherein the casing is comprised of a multilayer material, with one layer being significantly stronger than the layer that forms the surface of the casing facing the interior of the vapor chamber.

131. The vapor chamber as claimed in claim 130, wherein the multilayer casing material is formed by a cladding process.

132. The vapor chamber as claimed in claim 131, wherein the clad material is formed from one or more layers of metal or ceramic and at least one layer of copper or copper-bearing alloys.

133. The vapor chamber as claimed in claim 130, wherein the multilayer casing material is formed by affixing a plurality of material layers together through a joining process such as diffusion bonding, soldering, brazing or adhesive joining.

134. A method for manufacturing a vapor chamber structure, comprising:
providing a casing that is composed of at least one upper casings and at least one lower casings;
forming a wick layer on an internal surface of the casing; respectively arranging one or more structure strengthening bodies to support the casing;
bending a peripheral edge of the casing to form a double seam seal assembling the upper casing and the lower casing together to form a receiving chamber;
pumping away air from the receiving chamber to form an airtight vacuum chamber for supporting the casing; and filling a working fluid into the airtight vacuum chamber and sealing the casing.

135. The method as claimed in claim 134, further comprising a step of bending an edge of the upper casing before bending a peripheral edge of the casing to form a double seam seal.

136. A method for manufacturing a vapor chamber structure, comprising:
providing a casing that is composed of at least one upper casings and at least one lower casings;
forming a wick layer on an internal surface of the casing; respectively arranging a plurality of structure strengthening bodies to strengthen the casing;
creating a vacuum around the upper casing and the lower casing; introducing a working fluid between the casings;
bending a peripheral edge of the casing to form a double seam seal assembling the upper casing and the lower casing together to form an airtight vacuum chamber.

137. The method as claimed in claim 136, further comprising a step of bending an edge of the upper casing before bending a peripheral edge of the casing to form a double seam seal.

138. A vapor chamber structure, comprising:
a casing having an airtight vacuum chamber;
a working fluid filled into the airtight vacuum chamber;
a wick layer formed on an internal surface of the airtight vacuum chamber; and
a plurality of heat dissipating fins integrally formed with the casing.

139. The vapor chamber structure as claimed in claim 138, wherein the casing is formed by an extrusion process.

140. The vapor chamber structure as claimed in claim 139, wherein the casing is extruded and within that extrusion a vacuum chamber is formed by boring, drilling or machining.

141. The vapor chamber structure as claimed in claim 140, wherein the casing is extruded in an axial direction and has fins that extend radially from the casing body.

142. The vapor chamber structure as claimed in claim 141, wherein a mounting bracket is attached to the casing body.

143. The vapor chamber structure as claimed in claim 141, wherein a fan and fan housing is attached to the casing body, and the fan is aligned to flow air over the integral fins of the casing body.

144. The vapor chamber structure as claimed in claim 140, wherein the casing is extruded in a linear direction and has fins that align linearly with the casing body.

145. The vapor chamber structure as claimed in claim 144, wherein a mounting bracket is attached to the casing body.

146. The vapor chamber structure as claimed in claim 144, wherein a fan and fan housing is attached to the casing body, and the fan is aligned to flow air over the integral fins of the casing body.

147. The vapor chamber structure as claimed in claim 144, wherein a fan and fan housing is attached to the casing body, and the fan is aligned to flow air over the integral fins of the casing body.

148. A method for manufacturing a vapor chamber structure, comprising:
providing a casing with integral fins that is formed by extrusion; forming a chamber in the casing;
forming a wick layer on an internal surface of the casing; providing a cover;
joining the cover to the chamber in the casing to form a receiving chamber;
pumping away air from the receiving chamber to form an airtight vacuum chamber for supporting the casing; and
filling a working fluid into the airtight vacuum chamber and sealing the casing.
